(19) United States
(12) Patent Application Publication
(10) Pub. No.: US 2026/0114142 A1
(43) Pub. Date: Apr. 23, 2026

(54) DISPLAY PANEL AND ELECTRONIC DEVICE

(71) Applicant: Samsung Display Co., Ltd., Yongin-si (KR)

(72) Inventors: Jaehak Lee, Yongin-si (KR); Seungsue Ryu, Yongin-si (KR); Kikyung Youk, Yongin-si (KR); Daehyuk Im, Yongin-si (KR); Sungwoon Im, Yongin-si (KR)

(21) Appl. No.: 19/326,011

(22) Filed: Sep. 11, 2025

(30) Foreign Application Priority Data
Oct. 18, 2024 (KR) 10-2024-0143259

(51) Int. Cl. H10K 59/131; H10K 59/95

(52) U.S. Cl. CPC H10K 59/131; H10K 59/95

(57) ABSTRACT

A display panel and an electronic device are provided, and the display panel includes a substrate including a display area and a peripheral area, a pad disposed in the peripheral area of the substrate and including a pad electrode, an insulating layer disposed on the pad and defining an opening through which at least a part of the pad electrode is exposed to outside, and a pad connection electrode connected to the pad electrode through the opening and contacting a circuit board pad, at least a part of the pad connection electrode being disposed on the insulating layer.

This application claims priority to Korean Patent Application No. 10-2024-0143259, filed on Oct. 18, 2024, and all the benefits accruing therefrom under 35 U.S.C. § 119, the content of which in its entirety is herein incorporated by reference.

### BACKGROUND

### 1. Field

One or more embodiments relate to an apparatus, and more particularly, to a display panel and an electronic device.

### 2. Description of the Related Art

Mobility-based electronic devices are widely used. Recently, tablet personal computers (PCs), in addition to small electronic devices such as mobile phones, have been widely used as mobile electronic devices.

A mobile electronic device includes a display panel for providing visual information such as an image to a user, in order to support various functions. Recently, as other components for driving a display panel have been miniaturized, the proportion of a display panel in an electronic device has gradually increased, and a structure that is bendable from a flat state to have a certain angle has been developed.

### SUMMARY

In general, a display circuit board may be connected to a pad of a display panel. In this case, because a space should be secured at a rear end of the pad in order to connect the display circuit board to the pad, the size of a substrate of the display panel may increase. Also, when a part of the display circuit board is bent, force may be applied to the substrate of the display panel as a bending curvature of the display circuit board decreases, thereby damaging the substrate. One or more embodiments include a display panel and an electronic device in which the size of a peripheral area may be reduced by reducing the size of a substrate of a display panel, while reducing damage to the substrate of the display panel.

Additional aspects will be set forth in part in the description which follows and, in part, will be apparent from the description, or may be learned by practice of the presented embodiments.

According to one or more embodiments, a display panel includes a substrate including a display area and a peripheral area, a pad disposed in the peripheral area of the substrate and including a pad electrode, an insulating layer disposed on the pad and defining an opening through which at least a part of the pad electrode is exposed to outside, and a pad connection electrode connected to the pad electrode through the opening, at least a part of the pad connection electrode being disposed on the insulating layer.

In the present embodiment, the opening may include a plurality of openings, and the plurality of openings may be arranged in one direction crossing a longitudinal direction of the pad connection electrode in a plan view.

In the present embodiment, the opening may include a plurality of openings, and the plurality of openings may be arranged in a serpentine shape in one direction crossing a longitudinal direction of the pad connection electrode in a plan view.

In the present embodiment, the opening may have an elliptical shape in a plan view.

In an embodiment, the pad connection electrode may include an uneven portion in a cross-sectional view.

In an embodiment, the display panel may further include a protrusion disposed on the insulating layer and protruding toward the pad connection electrode.

In an embodiment, the protrusion may include a plurality of protrusions, and the plurality of protrusions may be arranged under a part of the pad connection electrode in a plan view and may be spaced apart from each other.

In an embodiment, the protrusion may have a linear shape in a plan view.

In the present embodiment, the protrusion may have a lattice shape in a plan view.

In the present embodiment, the insulating layer may include an organic material.

According to one or more embodiments, an electronic device includes a display panel, and a circuit board connected to the display panel and including a circuit board pad, and the display panel includes a substrate including a display area and a peripheral area, a pad disposed in the peripheral area of the substrate and defining a pad electrode, an insulating layer disposed on the pad and including an opening through which at least a part of the pad electrode is exposed to outside, and a pad connection electrode connected to the pad electrode through the opening and contacting the circuit board pad, at least a part of the pad connection electrode being disposed on the insulating layer.

In the present embodiment, the opening may include a plurality of openings, and the plurality of openings may be arranged in one direction crossing a longitudinal direction of the pad connection electrode in a plan view.

In the present embodiment, the opening may include a plurality of openings, and the plurality of openings may be arranged in a serpentine shape in one direction crossing a longitudinal direction of the pad connection electrode in a plan view.

In the present embodiment, the opening may have an elliptical shape in a plan view.

In an embodiment, the pad connection electrode may include an uneven portion in a cross-sectional view.

In an embodiment, the electronic device may further include a protrusion disposed on the insulating layer and protruding toward the pad connection electrode.

In an embodiment, the protrusion may include a plurality of protrusions, and the plurality of protrusions are disposed under a part of the pad connection electrode in a plan view and may be spaced apart from each other.

In an embodiment, the protrusion may have a linear shape in a plan view.

In the present embodiment, the protrusion may have a lattice shape in a plan view.

In the present embodiment, the insulating layer may include an organic material.

Other aspects, features, and advantages of the disclosure will become more apparent from the drawings, the claims, and the detailed description.

These general and specific embodiments may be implemented by using a system, a method, a computer program, or a combination thereof.

### BRIEF DESCRIPTION OF THE DRAWINGS

The above and other aspects, features, and advantages of certain embodiments will be more apparent from the following description taken in conjunction with the accompanying drawings, in which:

FIG. 1 is a perspective view schematically illustrating an electronic device, according to an embodiment;

FIG. 2 is an exploded perspective view schematically illustrating the electronic device of FIG. 1;

FIG. 3 is a block diagram schematically illustrating the electronic device of FIG. 1;

FIG. 4 is a plan view schematically illustrating a display panel, according to an embodiment;

FIG. 5 is an equivalent circuit diagram illustrating one pixel disposed in a display area of the display panel of FIG. 4;

FIG. 6 is a cross-sectional view taken along line B-B′ of FIG. 4;

FIG. 7A is a cross-sectional view schematically illustrating a part of the electronic device of FIG. 1;

FIG. 7B is a cross-sectional view schematically illustrating a part of the electronic device of FIG. 1;

FIG. 8 is an enlarged cross-sectional view illustrating a portion C of FIGS. 7A and 7B;

FIG. 9A is a plan view schematically illustrating a pad connection electrode of FIG. 8;

FIG. 9B is a plan view schematically illustrating a pad connection electrode of a display panel, according to another embodiment;

FIG. 10 is a cross-sectional view schematically illustrating a part of a display panel, according to another embodiment;

FIGS. 11A to 11C are plan views schematically illustrating a protrusion of FIG. 10;

FIG. 12 is a block diagram of an electronic device, according to an embodiment; and

FIGS. 13 to 15 are schematic views of electronic devices, according to various embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the detailed description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described in detail with reference to the accompanying drawings, wherein the same or corresponding elements are denoted by the same reference numerals throughout and a repeated description thereof is omitted.

Although the terms “first,” “second,” etc. may be used to describe various elements, these elements should not be limited by these terms. These terms are only used to distinguish one element from another.

As used herein, the singular forms “a,” “an,” and “the” are intended to include the plural forms as well, unless the context clearly indicates otherwise.

It will be further understood that the terms “comprises” or “comprising” used herein specify the presence of stated features or components, but do not preclude the presence or addition of one or more other features or components.

It will be further understood that, when a layer, region, or component is referred to as being “on” another layer, region, or component, it may be directly on the other layer, region, or component, or may be indirectly on the other layer, region, or component with intervening layers, regions, or components therebetween.

Sizes of components in the drawings may be exaggerated or reduced for convenience of explanation. For example, because sizes and thicknesses of components in the drawings are arbitrarily illustrated for convenience of explanation, the disclosure is not limited thereto.

In the following embodiments, the x-axis, the y-axis and the z-axis are not limited to three axes of the rectangular coordinate system, and may be interpreted in a broader sense. For example, the x-axis, the y-axis, and the z-axis may be perpendicular to one another or may represent different directions that are not perpendicular to one another.

When a certain embodiment may be implemented differently, a specific process order may be different from the described order. For example, two consecutively described processes may be performed substantially at the same time or may be performed in an order opposite to the described order.

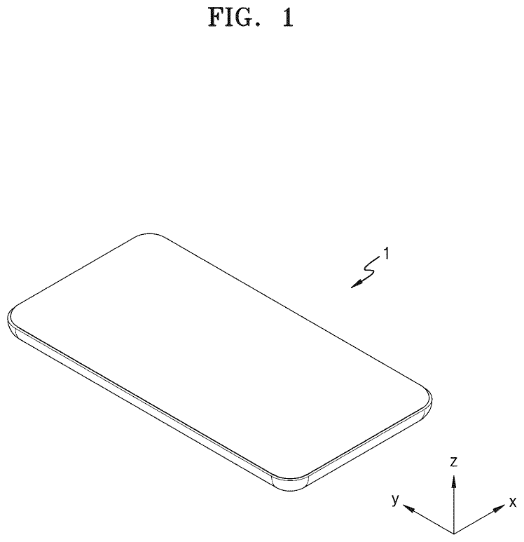

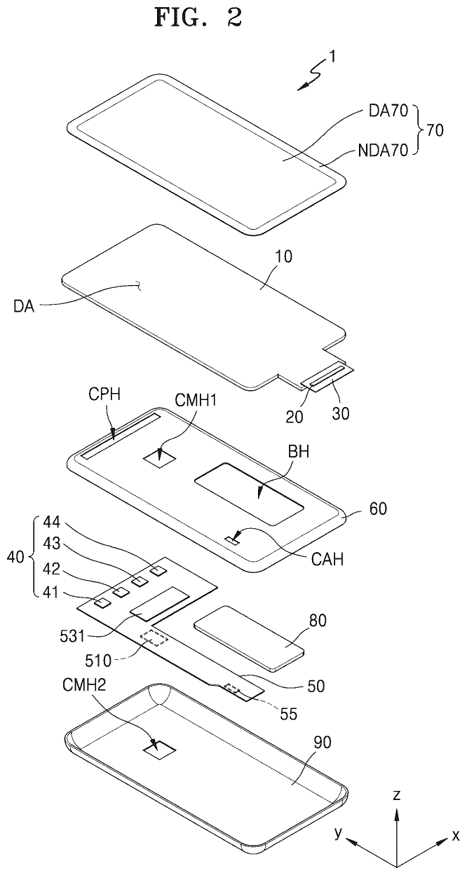

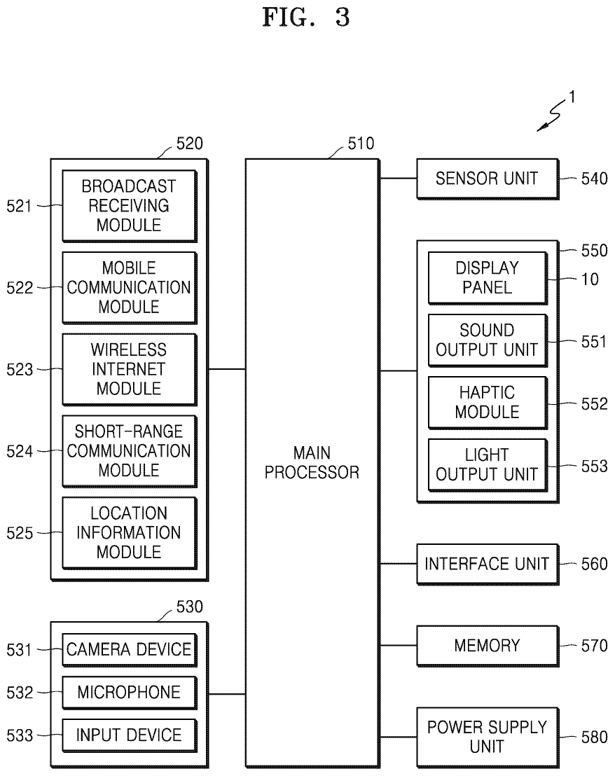

FIG. 1 is a perspective view schematically illustrating an electronic device, according to an embodiment. FIG. 2 is an exploded perspective view schematically illustrating the electronic device of FIG. 1. FIG. 3 is a block diagram schematically illustrating the electronic device of FIG. 1.

Referring to FIGS. 1 to 3, an electronic device 1 for displaying a moving image or a still image may be a portable electronic device such as a mobile phone, a smartphone, a tablet personal (PC) computer, a mobile communication terminal, an electronic organizer, an electronic book, a portable multimedia player (PMP), a navigation device, or an ultra-mobile PC (UMPC) or may be any of various products such as a television, a laptop computer, a monitor, an advertisement board, or an Internet of things (IoT) product. Alternatively, the electronic device 1 according to an embodiment may be a wearable device such as a smart watch, a watch phone, a glasses-type display, or a head-mounted display (HMD). Alternatively, the electronic device 1 according to an embodiment may be an instrument panel of a vehicle, a center fascia of a vehicle, or a center information display (CID) disposed on a dashboard of a vehicle, a room mirror display replacing a side-view mirror of a vehicle, or a display disposed on the back of a front seat for entertainment for a person in a back seat of a vehicle.

For convenience of explanation, in FIGS. 1 and 2, the electronic device 1 is a smartphone. The electronic device 1 may include a cover window 70, a display panel 10, a data driver 20, a display circuit board 30, a component 40, a bracket 60, a main circuit board 50, a battery 80, and/or a lower cover 90.

In the specification, the “plan view” refers to a view when the display panel 10 is viewed in a direction (z direction, hereinafter, may also be referred to as “z-axis direction”) perpendicular to the display panel 10, and “left,” “right,” “upper,” and “lower” in the plan view refer to directions when the display panel 10 is viewed in a direction perpendicular to the display panel 10. For example, “left” refers to an opposite direction of an x direction (hereinafter, may also be referred to as “x-axis direction”), “right” refers to an x direction, “upper” refers to a y direction (hereinafter, may also be referred to as “y-axis direction”), and “lower” refers to an opposite direction of a y direction.

In a plan view, the electronic device 1 may have a substantially rectangular shape. For example, the electronic device 1 may have a substantially rectangular shape having a short side in an x-axis direction and a long side in a y-axis direction in an xy plane as shown in FIG. 1. In this case, a corner where the short side in the x-axis direction and the long side in the y-axis direction meet each other may form a right angle, or may have a rounded shape with a certain curvature. However, the disclosure is not limited thereto, and in a plan view, the electronic device 1 may have a polygonal shape other than a rectangular shape, may have an elliptical shape, or an irregular shape.

The cover window 70 may be disposed on the display panel 10 to cover a top surface of the display panel 10. The cover window 70 may protect the top surface of the display panel 10.

The cover window 70 may include a transmissive cover portion DA70 corresponding to the display panel 10 and a light-blocking cover portion NDA70 surrounding the transmissive cover portion DA70. The light-blocking cover portion NDA70 may include an opaque material for blocking light (e.g., a colored opaque material). The light-blocking cover portion NDA70 may include a pattern that may be shown to a user when an image is not displayed.

The display panel 10 may be disposed under the cover window 70. The display panel 10 may overlap the transmissive cover portion DA70 of the cover window 70. The display panel 10 includes a display area DA. The display area DA where an image is displayed may include an area (hereinafter, referred to as a component area) where light emitted from the component 40 disposed under the display panel 10 is transmitted. The component may include a sensor or a camera using visible light, infrared light, or sound.

The display panel 10 may be a light-emitting display panel including a light-emitting diode. The light-emitting diode may be an organic light-emitting diode including an organic emission layer, or an inorganic light-emitting diode including an inorganic material. The inorganic light-emitting diode may include a PN junction diode including inorganic semiconductor-based materials. When a voltage is applied to a PN junction diode in a forward direction, holes and electrons may be injected, and energy generated by recombination of the holes and electrons may be converted into light energy to emit light of a certain color. The inorganic light-emitting diode may have a width of several micrometers to hundreds of micrometers. The inorganic light-emitting diode may be referred to as a micro LED.

The display panel 10 may be a rigid display panel that is rigid and is not easily bent, or a flexible display panel that is flexible and may be easily bent, folded, or rolled. For example, the display panel 10 may be a foldable display panel that may be folded and unfolded, a curved display panel with a curved display surface, a rollable display panel that may be rolled or unrolled, or a stretchable display panel.

The display panel 10 may be a transparent display panel that is transparent so that an object or a background disposed on a bottom surface of the display panel 10 is viewed from the top surface of the display panel 10. Alternatively, the display panel 10 may be a reflective display panel capable of reflecting an object or a background on the top surface of the display panel 10.

The data driver 20 may be mounted as an integrated circuit (IC) on the display circuit board 30.

The display circuit board 30 may be attached to one side of the display panel 10. The display circuit board 30 may be a flexible printed circuit board (FPCB), or a composite printed circuit board including both a rigid printed circuit board and a flexible printed circuit board. A touch sensor driver may be mounted on the display circuit board 30. The touch sensor driver may be formed as an integrated circuit. The touch sensor driver may be electrically connected to touch electrodes of a touchscreen layer of the display panel 10 through the display circuit board 30.

At least a portion of the display circuit board 30 may be bent. In this case, the display circuit board 30 may connect the display panel 10 to the main circuit board 50. In this case, the display circuit board 30 may be connected to a pad of the display panel 10, and may be bent to the bottom surface of the display panel 10.

The touchscreen layer of the display panel 10 may detect a touch input of the user by using at least one of various touch methods such as a resistive method or a capacitive method. When the touchscreen layer of the display panel 10 detects a touch input of the user by using a capacitive method, the touch sensor driver may apply driving signals to driving electrodes from among the touch electrodes, and may determine whether the user touches by detecting voltages charged in mutual capacitance between the driving electrodes and sensing electrodes through the sensing electrodes from among the touch electrodes.

The user's touch may include a contact touch and a proximity touch. The contact touch means that an object such as the user's finger or a pen directly contacts the cover window 70 disposed on the touchscreen layer. The proximity touch means that an object such as the user's finger or a pen is located close to the cover window 70, such as hovering. The touch sensor driver may transmit sensor data to a main processor 510 according to the detected voltages, and the main processor 510 may calculate touch coordinates where the touch input occurs by analyzing the sensor data.

A controller for supplying driving voltages for driving pixels of the display panel 10, a gate driver, and/or the data driver 20 may be disposed on the display circuit board 30.

The bracket 60 for supporting the display panel 10 may be disposed under the display panel 10. The bracket 60 may include plastic, metal, or both plastic and metal. The bracket 60 may include a first camera hole CMH1 into which a camera device 531 is inserted, a battery hole BH in which the battery 80 is disposed, a cable hole CAH through which a cable connected to the display circuit board 30 passes, and a component hole CPH corresponding to the components 40. The component hole CPH may overlap the components 40 of the main circuit board 50 when viewed in a third direction (a z-axis direction). For reference, the display area DA of the display panel 10 may overlap the components 40 of the main circuit board 50 when viewed in the third direction (the z-axis direction). When necessary, the bracket 60 may not have the component hole CPH.

The components 40 included in the electronic device 1 may include a first component 41, a second component 42, a third component 43, and a fourth component 44 overlapping the display panel 10. Each of the a first component 41, the second component 42, the third component 43, and the fourth component 44 may include at least one of a proximity sensor, an illumination sensor, an iris sensor, a facial recognition sensor, and a camera (or an image sensor). The proximity sensor using infrared rays may detect an object located close to a top surface of the electronic device 1, and the illuminance sensor may detect a brightness of light incident on the top surface of the electronic device 1. Also, the iris sensor may capture an image of the iris of a person located over the top surface of the electronic device 1, and the camera may obtain image data of the object located over the top surface of the electronic device 1. The component 40 is not limited to the proximity sensor, the illumination sensor, the iris sensor, the facial recognition sensor, and/or the camera, and may include another sensor.

The main circuit board 50 and the battery 80 may be disposed under the bracket 60. The main circuit board 50 may be a rigid printed circuit board or a flexible printed circuit board.

The main circuit board 50 may include the main processor 510, the camera device 531, a main connector 55, and the components 40. The main processor 510 may be formed as an integrated circuit. When necessary, the electronic device 1 may include not only the camera device 531 disposed on a top surface of the main circuit board 50 but also a camera device disposed on a bottom surface of the main circuit board 50. Each of the main processor 510 and the main connector 55 may be disposed on any one of the top surface and the bottom surface of the main circuit board 50. The main circuit board 50 may be electrically connected to the display circuit board 30 through the main connector 55 or the like.

The main processor 510 may control all functions of the electronic device 1. For example, the main processor 510 may output digital video data to the data driver 20 through the display circuit board 30 so that the display panel 10 displays an image. The main processor 510 may receive detection data from the touch sensor driver. The main processor 510 may determine whether the user touches according to the detection data, and may perform an operation corresponding to the user's direct touch (i.e., contact touch) or proximity touch. The main processor 510 may be an application processor, a central processing unit, or a system chip formed as an integrated circuit.

The camera device 531 processes an image frame such as a still image or a moving image obtained by an image sensor in a camera mode and outputs the image frame to the main processor 510. The camera device 531 may include at least one of a camera sensor (e.g., CCD or CMOS), a photo sensor (or image sensor), and a laser sensor.

A cable passing through the cable hole CAH of the bracket 60 may be connected to the main connector 55, and the main circuit board 50 may be electrically connected to the display circuit board 30 through the cable.

The electronic device 1 may be illustrated as a block diagram as shown in FIG. 3. The electronic device 1 may include a wireless communication unit 520, an input unit 530, a sensor unit 540, an output unit 550, an interface unit 560, a memory 570, and/or a power supply unit 580 as shown in FIG. 3, in addition to the main processor 510.

The wireless communication unit 520 may include at least one of a broadcast receiving module 521, a mobile communication module 522, a wireless Internet module 523, a short-range communication module 524, and a location information module 525.

The broadcast receiving module 521 receives a broadcast signal and/or broadcast-related information from an external broadcast management server through a broadcast channel. The broadcast channel may include a satellite channel and a terrestrial channel.

The mobile communication module 522 transmits and receives a wireless signal to and from at least one of a base station, an external terminal, and a server in a mobile communication network established according to technical standards or communication methods for mobile communication (e.g., global system for mobile communication (GSM), code division multi-access (CDMA), code division multi-access 2000 (CDMA2000), enhanced voice-data optimized or enhanced voice-data only (EV-DO), wideband CDMA (WCDMA), high speed downlink packet access (HSDPA), high speed uplink packet access (HSUPA), long term evolution (LTE), and long term evolution-advanced (LTE-A)). The wireless signal may include various types of data according to transmission and reception of a voice call signal, a video call signal, or a text/multimedia message.

The wireless Internet module 523 refers to a module for wireless Internet access. The wireless Internet module 523 may be configured to transmit and receive a wireless signal in a communication network according to wireless Internet technology. The wireless Internet technology may be, for example, wireless LAN (WLAN), wireless-fidelity (Wi-Fi), Wi-Fi direct, and/or digital living network alliance (DLNA).

The short-range communication module 524 for short-range communication may support short-range communication by using at least one of Bluetooth™, radio frequency identification (RFID), infrared data association (IrDA), ultra-wideband (UWB), ZigBee, near field communication (NFC), wireless-fidelity (Wi-Fi), Wi-Fi direct, and wireless universal serial bus (USB) technology. The short-range communication module 524 may support wireless communication between the electronic device 1 and a wireless communication system, between the electronic device 1 and another electronic device, or between the electronic device 1 and a network in which another electronic device (or an external server) is located through a wireless area network. The wireless area network may be a wireless personal area network. The other electronic device may be a wearable device that may exchange data (or interoperate) with the electronic device 1.

The location information module 525 for obtaining a location of the electronic device 1 may include a global positioning system (GPS) module or a wireless fidelity (Wi-Fi) module.

The input unit 530 may include an image input unit such as the camera device 531 for inputting an image signal, a sound input unit such as a microphone 532 for inputting a sound signal, and an input device 533 for receiving information from the user. The camera device 531 processes an image frame such as a still image or a moving image obtained by the image sensor in a video call mode or a photographing mode. The processed image frame may be displayed on the display panel 10 or may be stored in the memory 570. The microphone 532 processes an external sound signal into electrical voice data. The processed voice data may be used in various ways according to a function being performed (or an application being executed) in the electronic device 1.

The main processor 510 may control an operation of the electronic device 1 in response to information input through the input device 533. The input device 533 may include a mechanical input means or a touch input means such as a button, a dome switch, a jog wheel, or a jog switch located on a rear surface or a side surface of the electronic device 1. The touch input means may include the touchscreen layer of the display panel 10.

The sensor unit 540 may include one or more sensors that sense at least one of information in the electronic device 1, environment information surrounding the electronic device 1, and user information and generates a corresponding sensing signal. The main processor 510 may control the driving or operation of the electronic device 1 or may perform data processing, a function, or an operation related to an application installed in the electronic device 1. The sensor unit 540 may be a proximity sensor, an illumination sensor, or a facial recognition sensor as described with respect to the component 40. The sensor unit 540 may include an acceleration sensor, a magnetic sensor, a G-sensor, a gyroscope sensor, a motion sensor, an RGB sensor, an infrared (IR) sensor, a finger scan sensor, an ultrasonic sensor, an optical sensor, and/or a battery gauge. In addition, the sensor unit 540 may include an environmental sensor or a chemical sensor. The environmental sensor may be, for example, a barometer, a hygrometer, a thermometer, a radiation detection sensor, a heat sensor, and/or a gas sensor. The chemical sensor may be, for example, an electronic nose, a healthcare sensor, and/or a biometric sensor.

The output unit 550 for generating an output related to visual, auditory, or tactile sense may include at least one of the display panel 10, a sound output unit 551, a haptic module 552, and a light output unit 553.

The display panel 10 displays (outputs) information processed by the electronic device 1. For example, the display panel 10 may display execution screen information of an application running in the electronic device 1, may display a user interface (UI) according to the execution screen information, or may display graphical user interface (GUI) information. The display panel 10 may include a display layer for displaying an image and a touchscreen layer for detecting a touch input of the user. Accordingly, the display panel 10 may function as one of input devices 533 that provide an input interface between the electronic device 1 and the user and at the same time, may also function as one of output units 550 that provide an output interface between the electronic device 1 and the user.

The sound output unit 551 may output sound data received from the wireless communication unit 520 or stored in the memory 570, in a call signal reception mode, a call mode, a recording mode, a voice recognition mode, and/or a broadcast reception mode. The sound output unit 551 may output a sound signal related to a function (e.g., a call signal reception sound or a message reception sound) performed in the electronic device 1. The sound output unit 551 may include a receiver and a speaker. At least one of the receiver and the speaker may be a sound generating device that is attached to the bottom of the display panel 10 and outputs sound by vibrating the display panel 10. The sound generating device may be a piezoelectric element or a piezoelectric actuator that contracts or expands according to an electrical signal, or an exciter that generates a magnetic force by using a voice coil and vibrates the display panel 10.

The haptic module 552 generates various tactile effects that the user may feel. The haptic module 552 may provide vibration to the user as a tactile effect. The haptic module 552 may not only transfer a tactile effect through direct contact, but may also allow the user to feel a tactile effect through a muscle sense such as a finger or arm of the user.

The light output unit 553 outputs a signal for notifying the occurrence of an event by using light of a light source. Examples of events occurring in the electronic device 1 may include message reception, call signal reception, missed call, alarm, schedule notification, email reception, and/or information reception through an application. A signal output from the light output unit 553 is implemented as the electronic device 1 emits light of a single color or multiple colors from a front surface or a rear surface. The signal output may be terminated when the electronic device 1 detects that the user has confirmed the event.

The interface unit 560 functions as a passage with various types of external devices connected to the electronic device 1. The interface unit 560 may include at least one of a wired/wireless headset port, an external charger port, a wired/wireless data port, a memory card port, a port for connecting a device including an identification module, an audio input/output (I/O) port, a video I/O port, and an earphone port. When an external device is connected to the interface unit 560, the electronic device 1 may perform appropriate control related to the connected external device.

The memory 570 stores data that supports various functions of the electronic device 1. The memory 570 may store a plurality of applications (application programs) running in the electronic device 1 and pieces of data and/or instructions for an operation of the electronic device 1. At least some of the plurality of applications may be downloaded from an external server through wireless communication. The memory 570 may store an application for an operation of the main processor 510, and may temporarily store input/output data, for example, a phone book, a message, a still image, and/or a moving image. Also, the memory 570 may store haptic data for vibration of various patterns provided to the haptic module 552 and sound data related to various sounds provided to the sound output unit 551.

The memory 570 may include at least one type of storage medium among a flash memory type, a hard disk type, a solid state disk (SSD) type, a silicon disk drive (SDD) type, a multimedia card micro type, a card type memory (e.g., SD or XD memory), a random-access memory (RAM), a static random-access memory (SRAM), a read-only memory (ROM), an electrically erasable programmable read-only memory (EEPROM), a programmable read-only memory (PROM), a magnetic memory, a magnetic disk, and an optical disk.

The power supply unit 580 receives external power and/or internal power and supplies the power to each element included in the electronic device 1, under the control of the main processor 510. The power supply unit 580 may include the battery 80. Also, the power supply unit 580 may include a connection port, and the connection port may be an example of the interface unit 560 to which an external charger for supplying power is electrically connected to charge the battery 80. Alternatively, the power supply unit 580 may charge the battery 80 in a wireless manner. The battery 80 may be disposed so as not to overlap the main circuit board 50 in the third direction (z direction). The battery 80 may overlap the battery hole BH of the bracket 60.

The lower cover 90 may form an outer appearance of the electronic device 1 and may define an opening through which a part of the display panel 10 is exposed. The lower cover 90 has a shape whose surface corresponding to the display panel 10 is open, and may be fastened to the display panel 10. The lower cover 90 may be located opposite to the cover window 70 with the display panel 10 therebetween. The lower cover 90 may be disposed under the main circuit board 50 and the battery 80. The lower cover 90 may be fastened and fixed to the bracket 60. The lower cover 90 may form an outer appearance of a bottom surface of the electronic device 1. The lower cover 90 may include plastic, metal, or both plastic and metal.

A second camera hole CMH2 through which a bottom surface of the camera device 531 is exposed may be formed in the lower cover 90. A position of the camera device 531, and positions of the first camera hole CMH1 and the second camera hole CMH2 corresponding to the camera device 531 are not limited to those illustrated in FIG. 2 and may be changed in various ways.

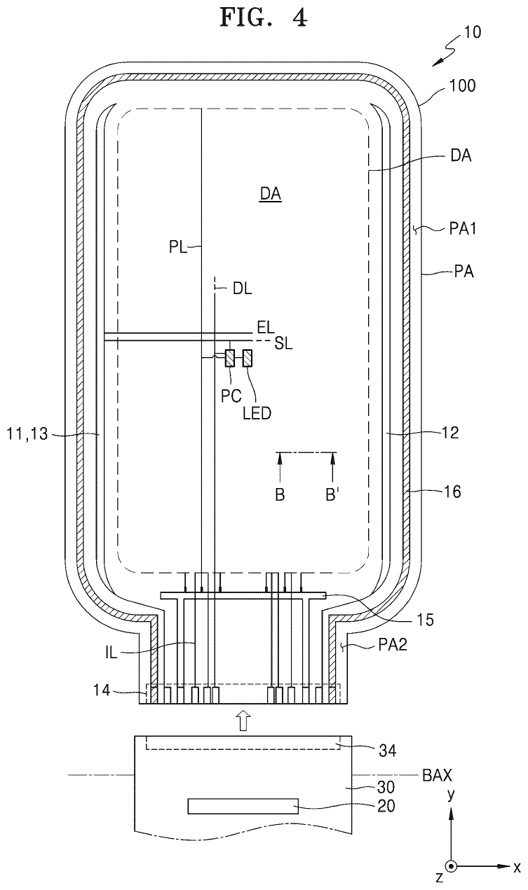

FIG. 4 is a plan view schematically illustrating a display panel, according to an embodiment.

Referring to FIG. 4, the display panel 10 may include the display area DA and a peripheral area PA outside the display area DA. The display area DA is a portion where an image is displayed, and a plurality of pixels may be located in the display area DA. The display area DA may have any of various shapes such as a circular shape, an elliptical shape, a polygonal shape, or a shape of a specific figure. In FIG. 4, the display area DA has a substantially rectangular shape with rounded corners.

The peripheral area PA may be located outside the display area DA. The peripheral area PA may include a first peripheral area PA1 surrounding at least a part of the display area DA and a second peripheral area PA2 located at a lower end of the display area DA and extending in a first direction (x-axis direction). A width of the second peripheral area PA2 in the first direction (the x-axis direction) may be less than a width of the display area DA. Through this structure, at least a part of the second peripheral area PA2 may be easily bent.

A planar shape of the display panel 10 of FIG. 4 may be substantially the same as a shape of a substrate 100 included in the display panel 10. As used herein, the “planar shape” is a shape of an object in a plan view. When the display panel 10 includes the display area DA and the peripheral area PA outside the display area DA, it may mean that the substrate 100 includes the display area DA and the peripheral area PA outside the display area DA. For convenience, the following will be described assuming that the substrate 100 includes the display area DA and the peripheral area PA.

The display panel 10 may include the substrate 100. Various elements of the display panel 10 may be disposed on the substrate 100.

Sub-pixels may be disposed in the display area DA, and the display area DA may provide an image by using light emitted from the sub-pixels. Each sub-pixel may include a light-emitting diode LED, and the light-emitting diode LED may be electrically connected to a sub-pixel circuit PC. The sub-pixel circuit PC and the light-emitting diode LED may be disposed in the display area DA. For convenience, although the sub-pixel circuit PC and the light-emitting diode LED are located side by side in FIG. 4, the sub-pixel circuit PC and the light-emitting diode LED may actually at least partially overlap each other. For example, the light-emitting diode LED may be disposed on the sub-pixel circuit PC.

A gate driving circuit, a pad 14, a first power supply wiring 15, and a second power supply wiring 16 may be disposed in the peripheral area PA. The gate driving circuit may include, for example, a first scan driving circuit 11, a second scan driving circuit 12, and/or an emission control driving circuit 13.

The first scan driving circuit 11 may provide a scan signal to the sub-pixel circuit PC through a scan line SL. The second scan driving circuit 12 may be disposed opposite to the first scan driving circuit 11 with the display area DA therebetween. Some of the sub-pixel circuits PC disposed in the display area DA may be electrically connected to the first scan driving circuit 11, and the rest may be connected to the second scan driving circuit 12. When necessary, the second scan driving circuit 12 may be omitted.

The emission control driving circuit 13 may be disposed on one side of the display area DA, like the first scan driving circuit 11. The emission control driving circuit 13 may provide an emission control signal to a pixel through the emission control line EL. Although the emission control driving circuit 13 is disposed only on one side of the display area DA in FIG. 4, the disclosure is not limited thereto. For example, the display panel 10 may include emission control driving circuits 13 disposed on one side and the other side of the display area DA. Alternatively, the first scan driving circuit 11 may be disposed on one side of the display area DA and the emission control driving circuit 13 may be disposed on the other side.

The pad 14 may be disposed in the second peripheral area PA2 of the substrate 100. The pad 14 may be electrically connected to the display circuit board 30. A circuit board pad 34 of the display circuit board 30 may be electrically connected to the pad 14 of the display panel 10.

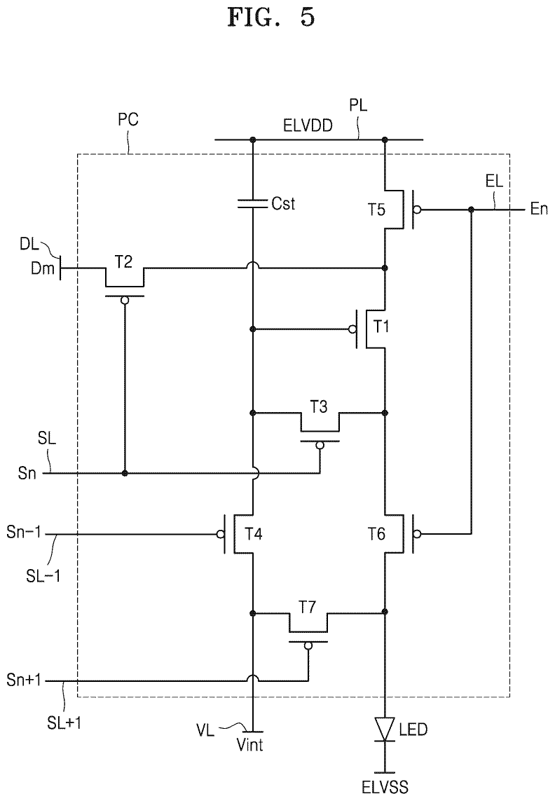

The display circuit board 30 transmits a signal or power of a controller to the display panel 10. A control signal generated by the controller may be transmitted to the gate driving circuit through the display circuit board 30. Also, the controller may provide a first power supply voltage ELVDD (see FIG. 5) and a second power supply voltage ELVSS (see FIG. 5) to the first power supply wiring 15 and the second power supply wiring 16, respectively. The first power supply voltage ELVDD (hereinafter, referred to as a driving voltage) may be provided to each sub-pixel circuit PC through a driving voltage line PL connected to the first power supply wiring 15, and the second power supply voltage ELVSS (hereinafter, referred to as a common voltage) may be provided to a common electrode (hereinafter, referred to as a second electrode or a cathode) of the light-emitting diode LED connected to the second power supply wiring 16. The first power supply wiring 15 may extend in the first direction (the x-axis direction). The second power supply wiring 16 may have a loop shape with one side open and may partially surround the display area DA.

The display circuit board 30 may be bent around a bending axis BAX. For example, a part of the display circuit board 30 may be connected to the pad 14 of the display panel 10, and another part of the display circuit board 30 may be connected to the part of the display circuit board 30 and may be bent around the bending axis BAX to be disposed on a bottom surface of the display panel 10.

A data signal of the data driver 20 may be transmitted to the sub-pixel circuit PC through an input line IL connected to the pad 14 through the circuit board pad 34 disposed on the display circuit board 30 and through a data line DL electrically connected to the input line IL.

FIG. 5 is an equivalent circuit diagram illustrating one pixel disposed in a display area of the display panel of FIG. 4.

Referring to FIG. 5, the light-emitting diode LED may be electrically connected to the sub-pixel circuit PC.

The sub-pixel circuit PC may include a first thin-film transistor T1, a second thin-film transistor T2, a third thin-film transistor T3, a fourth thin-film transistor T4, a fifth thin-film transistor T5, a sixth thin-film transistor T6, a seventh thin-film transistor T7, and a storage capacitor Cst.

The second thin-film transistor T2 that is a switching thin-film transistor may be connected to the scan line SL and the data line DL, and may transmit a data voltage (or a data signal Dm) input from the data line DL to the first thin-film transistor T1 based on a scan voltage (or a scan signal Sn) input from the scan line SL. The storage capacitor Cst may be connected to a gate electrode of the first thin-film transistor T1 and the driving voltage line PL, and may store a voltage corresponding to a difference between a voltage of the gate electrode of the first thin-film transistor T1 and the first power supply voltage ELVDD supplied to the driving voltage line PL.

The first thin-film transistor T1 that is a driving thin-film transistor may be connected to the driving voltage line PL and the storage capacitor Cst, and may control driving current flowing from the driving voltage line PL to the light-emitting diode LED in response to a value of the voltage stored in the storage capacitor Cst. The light-emitting diode LED may emit light having a certain luminance due to the driving current. A second electrode (e.g., a cathode) of the light-emitting diode LED may receive the second power supply voltage ELVSS.

A gate electrode of the third thin-film transistor T3 that is a compensation thin-film transistor may be connected to the scan line SL. A source electrode (or a drain electrode) of the third thin-film transistor T3 may be connected to a drain electrode (or a source electrode) of the first thin-film transistor T1, and may be connected to a first electrode of the light-emitting diode LED via the sixth thin-film transistor T6. The drain electrode (or the source electrode) of the third thin-film transistor T3 may be connected to one electrode of the storage capacitor Cst, a source electrode (or a drain electrode) of the fourth thin-film transistor T4, and a gate electrode of the first thin-film transistor T1. The third thin-film transistor T3 is turned on according to the scan signal Sn received through the scan line SL, and diode-connects the first thin-film transistor T1 by connecting the gate electrode and the drain electrode of the first thin-film transistor T1.

A gate electrode of the fourth thin-film transistor T4 that is an initialization thin-film transistor may be connected to a previous scan line SL-1. The drain electrode (or the source electrode) of the fourth thin-film transistor T4 may be connected to an initialization voltage line VL. The source electrode (or the drain electrode) of the fourth thin-film transistor T4 may be connected to one electrode of the storage capacitor Cst, the drain electrode (or the source electrode) of the third thin-film transistor T3, and the gate electrode of the first thin-film transistor T1. The fourth thin-film transistor T4 may be turned on according to a previous scan signal Sn-1 received through the previous scan line SL-1, and may perform an initialization operation of initializing a voltage of the gate electrode of the first thin-film transistor T1 by supplying an initialization voltage Vint to the gate electrode of the first thin-film transistor T1.

A gate electrode of the fifth thin-film transistor T5 that is an operation control thin-film transistor may be connected to an emission control line EL. A source electrode (or a drain electrode) of the fifth thin-film transistor T5 may be connected to the driving voltage line PL. The drain electrode (or the source electrode) of the fifth thin-film transistor T5 is connected to the source electrode (or the drain electrode) of the first thin-film transistor T1 and a drain electrode (or a source electrode) of the second thin-film transistor T2.

A gate electrode of the sixth thin-film transistor T6 that is an emission control thin-film transistor may be connected to the emission control line EL. A source electrode (or a drain electrode) of the sixth thin-film transistor T6 may be connected to the drain electrode (or the source electrode) of the first thin-film transistor T1 and the source electrode (or the drain electrode) of the third thin-film transistor T3. The drain electrode (or the source electrode) of the sixth thin-film transistor T6 may be electrically connected to the first electrode of the light-emitting diode LED. The fifth thin-film transistor T5 and the sixth thin-film transistor T6 may be simultaneously turned on according to an emission control signal En received through the emission control line EL, and thus the first power supply voltage ELVDD is supplied to the light-emitting diode LED and driving current flows through the light-emitting diode LED.

The seventh thin-film transistor T7 may be an initialization thin-film transistor for initializing the first electrode of the light-emitting diode LED. A gate electrode of the seventh thin-film transistor T7 may be connected to a next scan line SL+1. A source electrode (or a drain electrode) of the seventh thin-film transistor T7 may be connected to the first electrode of the light-emitting diode LED. The drain electrode (or the source electrode) of the seventh thin-film transistor T7 may be connected to the initialization voltage line VL. The seventh thin-film transistor T7 may be turned on according to a next scan signal Sn+1 received through the next scan line SL+1, and may initialize the first electrode of the light-emitting diode LED.

Although the fourth thin-film transistor T4 and the seventh thin-film transistor T7 are respectively connected to the previous scan line SL−1 and the next scan line SL+1 in FIG. 5, in another embodiment, both the fourth thin-film transistor T4 and the seventh thin-film transistor T7 may be connected to the previous scan line SL−1 and may be driven according to the previous scan signal Sn−1.

The other electrode of the storage capacitor Cst may be connected to the driving voltage line PL. One electrode of the storage capacitor Cst may be connected to the gate electrode of the first thin-film transistor T1, the drain electrode (or the source electrode) of the third thin-film transistor T3, and the source electrode (or the drain electrode) of the fourth thin-film transistor T4.

The second electrode (e.g., cathode) of the light-emitting diode LED receives the second power supply voltage ELVSS. The light-emitting diode LED receives driving current from the first thin-film transistor T1 and emits light.

The light-emitting diode LED may be an organic light-emitting diode including an organic material as a light-emitting material. In another embodiment, the light-emitting diode LED may be an inorganic light-emitting diode including an inorganic material. The inorganic light-emitting diode may include a PN junction diode including inorganic semiconductor-based materials. When a voltage is applied to a PN junction diode in a forward direction, holes and electrons may be injected, and energy generated by recombination of the holes and electrons may be converted into light energy to emit light of a certain color. The inorganic light-emitting diode may have a width of several to hundreds of micrometers, or several to hundreds of nanometers. In some embodiments, the light-emitting diode LED may include a quantum-dot light-emitting diode. As described above, an emission layer of the light-emitting diode LED may include an organic material, may include an inorganic material, may include quantum dots, may include an organic material and quantum dots, or may include an inorganic material and quantum dots. For convenience of explanation, the following will be described assuming that the light-emitting diode LED includes an organic light-emitting diode.

Although the sub-pixel circuit PC includes seven transistors and one capacitor in FIG. 5, in another embodiment, the sub-pixel circuit PC may include two or more transistors and may include two or more capacitors. Also, a circuit design of the sub-pixel circuit PC is not limited to that illustrated in FIG. 5 and may be changed in various ways.

The first to seventh thin-film transistors T1, T2, T3, T4, T5, T6, and T7 may be various types of transistors. In an embodiment, as shown in FIG. 5, all of the first to seventh thin-film transistors T1, T2, T3, T4, T5, T6, and T7 may be p-channel MOSFETs (PMOS). In another embodiment, at least one of the first to seventh thin-film transistors T1, T2, T3, T4, T5, T6, and T7 may be a PMOS, and the rest may be n-channel MOSFETs (NMOS). In another embodiment, all of the first to seventh thin-film transistors T1, T2, T3, T4, T5, T6, and T7 may be NMOS transistors. Positions of sources and drains may be changed according to a type (a p-type or an n-type) of a transistor.

All of the first to seventh thin-film transistors T1, T2, T3, T4, T5, T6, and T7 of FIG. 5 may be transistors including a low-temperature silicon semiconductor. In this case, the first to seventh thin-film transistors T1, T2, T3, T4, T5, T6, and T7 are not limited thereto, and at least one of the first to seventh thin-film transistors T1, T2, T3, T4, T5, T6, and T7 may be a transistor having a low-temperature polycrystalline silicon (LTPS) semiconductor layer, and the rest may be transistors having an oxide semiconductor layer. Alternatively, all of the first to seventh thin-film transistors T1, T2, T3, T4, T5, T6, and T7 may be transistors having an oxide semiconductor layer.

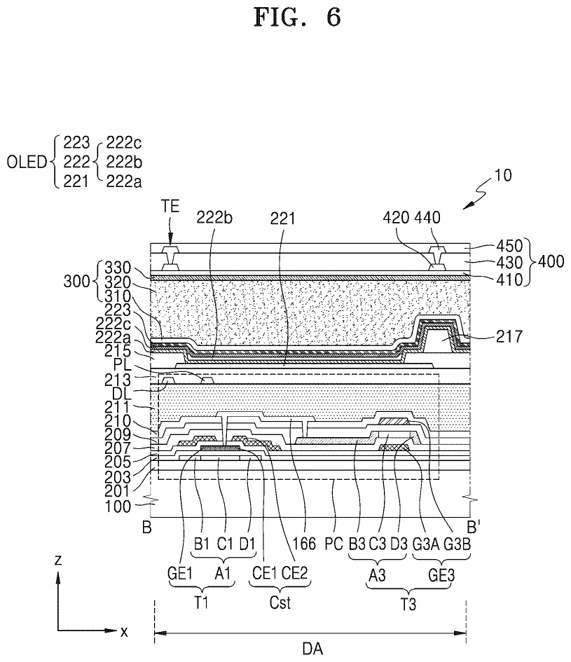

FIG. 6 is a cross-sectional view taken along line B-B′ of FIG. 4.

FIG. 6 illustrates the sub-pixel circuit PC and a light-emitting diode, for example, an organic light-emitting diode OLED, located in the display area DA of the display panel 10.

The substrate 100 may include glass, ceramic, a metal, or a polymer resin. In an embodiment, the substrate 100 may have a structure in which a base layer including a polymer resin and a barrier layer including an inorganic insulating material such as silicon oxide or silicon nitride are alternately stacked. When the substrate 100 has a stacked structure including a base layer formed of a polymer resin and a barrier layer formed of an inorganic insulating material, the flexibility of the electronic device 1 may be improved, and thus, a foldable electronic device 1 may be provided.

The inorganic insulating material may include silicon oxide, silicon nitride, or silicon oxynitride.

The polymer resin may include polyethersulfone, polyacrylate, polyetherimide, polyethylene naphthalate, polyethylene terephthalate, polyphenylene sulfide, polyarylate, polyimide, polycarbonate, or cellulose acetate propionate. For convenience of explanation, the following will be described in detail assuming that the substrate 100 is formed of a glass material.

The sub-pixel circuit PC may be formed on the substrate 100, and a light-emitting diode, for example, the organic light-emitting diode OLED, may be formed on the sub-pixel circuit PC.

Before the sub-pixel circuit PC is formed on the substrate 100, a buffer layer 201 may be formed on the substrate 100 to prevent impurities from penetrating into the sub-pixel circuit PC. The buffer layer 201 include an inorganic insulating material such as silicon nitride, silicon oxynitride, or silicon oxide, and may have a single or multi-layer structure including the above inorganic insulating material.

The sub-pixel circuit PC may include a plurality of transistors and a storage capacitor as described with reference to FIG. 5. In this regard, FIG. 6 illustrates the first thin-film transistor T1, the third thin-film transistor T3, and the storage capacitor Cst.

The first thin-film transistor T1 may include a semiconductor layer (hereinafter, referred to as a first semiconductor layer A1) on the buffer layer 201 and a gate electrode (hereinafter, referred to as a first gate electrode GE1) overlapping a channel region C1 of the first semiconductor layer A1. The first semiconductor layer A1 may include a silicon-based semiconductor material, for example, polysilicon. The first semiconductor layer A1 may include the channel region C1, and a first region B1 and a second region D1 disposed on both sides of the channel region C1. The first region B1 and the second region D1 are regions having a higher impurity concentration than the channel region C1, and one of the first region B1 and the second region D1 may correspond to a source region and the other may correspond to a drain region.

A first gate insulating layer 203 may be disposed between the first semiconductor layer A1 and the first gate electrode GE1. The first gate insulating layer 203 may include an inorganic insulating material such as silicon oxide, silicon nitride, or silicon oxynitride, and may have a single or multi-layer structure including the above inorganic insulating material.

The first gate electrode GE1 may include a conductive material including molybdenum (Mo), aluminum (Al), copper (Cu), or titanium (Ti), and may have a single or multi-layer structure including the above material.

The storage capacitor Cst may include a lower electrode CE1 and an upper electrode CE2 overlapping each other. In an embodiment, the lower electrode CE1 of the storage capacitor Cst may include the first gate electrode GE1. In other words, the first gate electrode GE1 may include the lower electrode CE1 of the storage capacitor Cst. For example, the first gate electrode GE1 and the lower electrode CE1 of the storage capacitor Cst may be integrally formed with each other.

A first interlayer insulating layer 205 may be disposed between the lower electrode CE1 and the upper electrode CE2 of the storage capacitor Cst. The first interlayer insulating layer 205 may include an inorganic insulating material such as silicon oxide, silicon nitride, or silicon oxynitride, and may have a single or multi-layer structure including the above inorganic insulating material.

The upper electrode CE2 of the storage capacitor Cst may include a low-resistance conductive material such as molybdenum (Mo), aluminum (Al), copper (Cu), and/or titanium (Ti), and may have a single or multi-layer structure including the above material.

A second interlayer insulating layer 207 may be disposed on the storage capacitor Cst. The second interlayer insulating layer 207 may include an inorganic insulating material such as silicon oxide, silicon nitride, or silicon oxynitride, and may have a single or multi-layer structure including the above inorganic insulating material.

A semiconductor layer (hereinafter, referred to as a third semiconductor layer A3) of the third thin-film transistor T3 may be disposed on the second interlayer insulating layer 207. The third semiconductor layer A3 may include a silicon-based semiconductor material, for example, polysilicon.

The third semiconductor layer A3 may include the channel region C3, and a first region B3 and a second region D3 disposed on both sides of the channel region C3. Any one of the first area B3 and the second area D3 may be a source region, and the other may be a drain region.

The third thin-film transistor T3 may include a gate electrode (hereinafter, referred to as a third gate electrode GE3) overlapping the channel region C3 of the third semiconductor layer A3. The third gate electrode GE3 may have a dual gate structure including a lower gate electrode G3A disposed under the third semiconductor layer A3 and an upper gate electrode G3B disposed over the channel region C3.

The lower gate electrode G3A may be disposed on the same layer (e.g., the first interlayer insulating layer 205) as the upper electrode CE2 of the storage capacitor Cst. The lower gate electrode G3A may include the same material as the upper electrode CE2 of the storage capacitor Cst.

The upper gate electrode G3B may be disposed over the third semiconductor layer A3 with a second gate insulating layer 209 therebetween. The second gate insulating layer 209 may include an inorganic insulating material such as silicon oxide, silicon nitride, or silicon oxynitride, and may have a single or multi-layer structure including the above inorganic insulating material.

A third interlayer insulating layer 210 may be disposed on the upper gate electrode G3B. The third interlayer insulating layer 210 may include an inorganic insulating material such as silicon oxynitride, and may have a single or multi-layer structure including the above inorganic insulating material.

Although FIG. 6 illustrates the first thin-film transistor T1 and the third thin-film transistor T3 from among the plurality of thin-film transistors described with reference to FIG. 5 and illustrates that the first semiconductor layer A1 and the third semiconductor layer A3 are disposed on different layers, the disclosure is not limited thereto.

Each of the second, fourth, fifth, sixth, and seventh thin-film transistors T2, T4, T5, T6, and T7 (see FIG. 5) described with reference to FIG. 5 may have the same structure as the first thin-film transistor T1 described with reference to FIG. 6. For example, each of the second, fourth, fifth, sixth, and seventh thin-film transistors T2, T4, T5, T6, and T7 (see FIG. 5) may include a semiconductor layer disposed on the same layer as the first semiconductor layer A1 of the first thin-film transistor T1, and a gate electrode disposed on the same layer as the first gate electrode GE1 of the first thin-film transistor T1. The semiconductor layers of the second, fourth, fifth, sixth, and seventh thin-film transistors T2, T4, T5, T6, and T7 (see FIG. 5) may be integrally connected to the first semiconductor layer A1.

The first thin-film transistor T1 and the third thin-film transistor T3 may be electrically connected to each other through a node connection line 166. The node connection line 166 may be disposed on the third interlayer insulating layer 210. One side of the node connection line 166 may be connected to the first gate electrode GE1 of the first thin-film transistor T1, and the other side of the node connection line 166 may be connected to the third semiconductor layer A3 of the third thin-film transistor T3.

The node connection line 166 may include aluminum (Al), copper (Cu), and/or titanium (Ti), and may have a single or multi-layer structure including the above material. For example, the node connection line 166 may have a three-layer structure including a titanium layer, an aluminum layer, and a titanium layer.

A first organic insulating layer 211 may be disposed on the node connection line 166. The first organic insulating layer 211 may include an organic insulating material. The organic insulating material may include acryl, benzocyclobutene (BCB), polyimide, or hexamethyldisiloxane (HMDSO).

The data line DL and the driving voltage line PL may be disposed on the first organic insulating layer 211 and may be covered by a second organic insulating layer 213. Each of the data line DL and the driving voltage line PL may include aluminum (Al), copper (Cu), and/or titanium (Ti), and may have a single or multi-layer structure including the above material. For example, each of the data line DL and the driving voltage line PL may have a three-layer structure including a titanium layer, an aluminum layer, and a titanium layer.

The second organic insulating layer 213 may include an organic insulating material such as acryl, BCB, polyimide, and/or HMDSO. Although the data line DL and the driving voltage line PL are formed on the first organic insulating layer 211 in FIG. 6, the disclosure is not limited thereto. In another embodiment, any one of the data line DL and the driving voltage line PL may be disposed on the same layer, e.g., the third interlayer insulating layer 210, as the node connection line 166.

The light-emitting diode, for example, the organic light-emitting diode OLED, may be disposed on the second organic insulating layer 213.

A first electrode 221 of the organic light-emitting diode OLED may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. In another embodiment, the first electrode 221 may further include a conductive oxide layer over and/or under the reflective film. The conductive oxide layer may include indium tin oxide (ITO), indium zinc oxide (IZO), zinc oxide (ZnO), indium oxide (In₂O₃), indium gallium oxide (IGO), and/or aluminum zinc oxide (AZO). In an embodiment, the first electrode 221 may have a three-layer structure including an ITO layer, an Ag layer, and an ITO layer.

A bank layer 215 may be disposed on the first electrode 221. The bank layer 215 may define an opening overlapping the first electrode 221 and may cover an edge of the first electrode 221. The bank layer 215 may include an organic insulating material such as polyimide.

An intermediate layer 222 includes an emission layer 222b. The intermediate layer 222 may include a first functional layer 222a disposed under the emission layer 222b and/or a second functional layer 222c disposed over the emission layer 222b. The emission layer 222b may include a high molecular weight organic material or a low molecular weight organic material that emits light of a certain color. The second functional layer 222c may include an electron transport layer (ETL) and/or an electron injection layer (EIL). Each of the first functional layer 222a and the second functional layer 222c may include an organic material.

A second electrode 223 may be formed of a conductive material having a low work function. For example, the second electrode 223 may include a (semi-)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the second electrode 223 may further include a layer formed of ITO, IZO, ZnO, or In₂O₃ on the (semi-)transparent layer including the above material.

The emission layer 222b may be formed in the display area DA to overlap the first electrode 221 through the opening of the bank layer 215. On the other hand, the first functional layer 222a, the second functional layer 222c, and the second electrode 223 may entirely cover the display area DA.

A spacer 217 may be formed on the bank layer 215. The spacer 217 and the bank layer 215 may be formed together in the same process or may be individually formed in separate processes. In an embodiment, the spacer 217 may include an organic insulating material such as polyimide. Alternatively, the bank layer 215 may include an organic insulating material including a light-blocking dye, and the spacer 217 may include an organic insulating material such as polyimide.

The organic light-emitting diode OLED may be covered by an encapsulation layer 300. The encapsulation layer 300 may include at least one organic encapsulation layer and at least one inorganic encapsulation layer. In an embodiment, in FIG. 6, the thin-film encapsulation layer 300 includes first and second inorganic encapsulation layers 310 and 330, and an organic encapsulation layer 320 disposed between the first and second inorganic encapsulation layers 310 and 330.

Each of the first and second inorganic encapsulation layers 310 and 330 may include at least one inorganic material from among aluminum oxide, titanium oxide, tantalum oxide, hafnium oxide, zinc oxide, silicon oxide, silicon nitride, and silicon oxynitride. Each of the first inorganic encapsulation layer 310 and the second inorganic encapsulation layer 330 may have a single or multi-layer structure including the above material. The organic encapsulation layer 320 may include a polymer-based material. Examples of the polymer-based material may include an acrylic resin, an epoxy resin, polyimide, and polyethylene. In an embodiment, the organic encapsulation layer 320 may include acrylate.

Thicknesses of the first inorganic encapsulation layer 310 and the second inorganic encapsulation layer 330 may be different from each other. A thickness of the first inorganic encapsulation layer 310 may be greater than a thickness of the second inorganic encapsulation layer 330. Alternatively, a thickness of the second inorganic encapsulation layer 330 may be greater than a thickness of the first inorganic encapsulation layer 310, or thicknesses of the first inorganic encapsulation layer 310 and the second inorganic encapsulation layer 330 may be the same.

An input sensing layer 400 may be disposed on the encapsulation layer 300. The input sensing layer 400 may include touch electrodes TE and at least one touch insulating layer disposed in the display area DA. In this regard, in FIG. 6, the input sensing layer 400 includes a first touch insulating layer 410 on the second inorganic encapsulation layer 330, a first conductive line 420 on the first touch insulating layer 410, a second touch insulating layer 430 on the first conductive line 420, a second conductive line 440 on the second touch insulating layer 430, and a third touch insulating layer 450 on the second conductive line 440.

Each of the first touch insulating layer 410, the second touch insulating layer 430, and the third touch insulating layer 450 may include an inorganic insulating material and/or an organic insulating material. In an embodiment, each of the first touch insulating layer 410 and the second touch insulating layer 430 may include an inorganic insulating material such as silicon oxide, silicon nitride, and/or silicon oxynitride, and the third touch insulating layer 450 may include an organic insulating material.

Each of the touch electrodes TE of the input sensing layer 400 may have a structure in which the first conductive line 420 and the second conductive line 440 are connected to each other. Alternatively, the touch electrode TE may include any one of the first conductive line 420 and the second conductive line 440, and in this case, the second touch insulating layer 430 may be omitted.

Each of the first conductive line 420 and the second conductive line 440 may include aluminum (Al), copper (Cu), and/or titanium (Ti), and may have a single or multi-layer structure including the above material. For example, each of the first conductive line 420 and the second conductive line 440 may have a three-layer structure including a titanium layer, an aluminum layer, and a titanium layer.

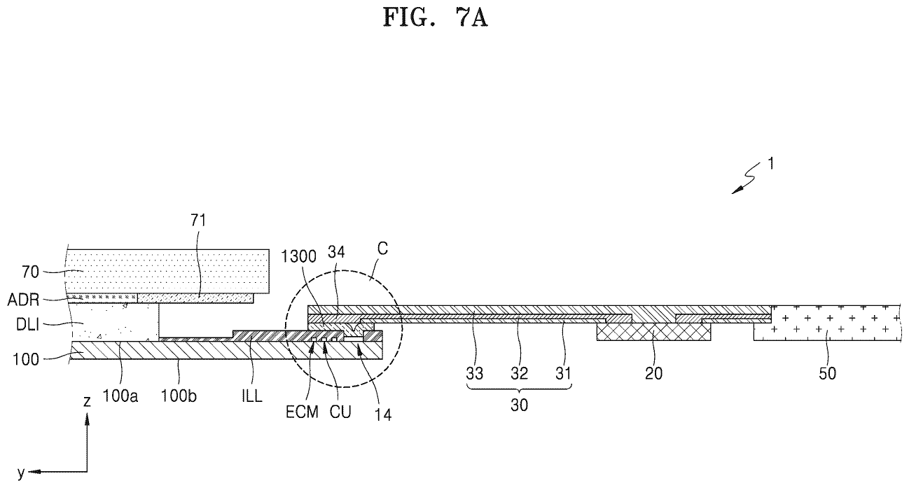

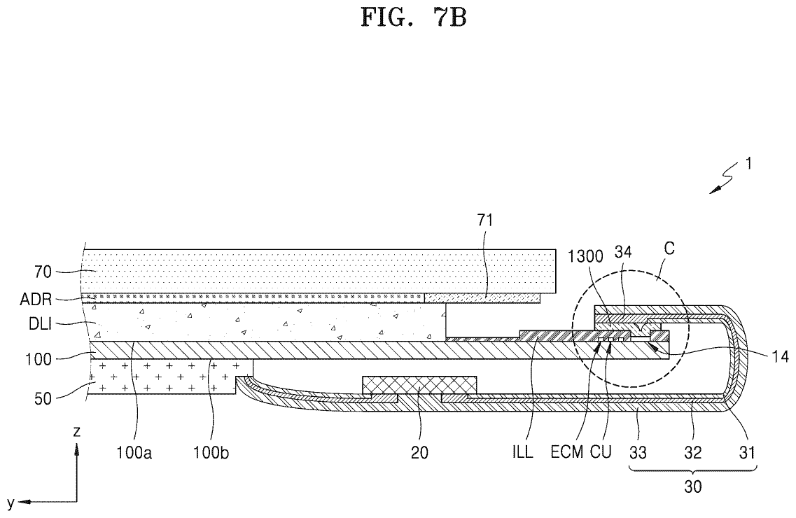

FIG. 7A is a cross-sectional view schematically illustrating a part of the electronic device of FIG. 1. FIG. 7B is a cross-sectional view schematically illustrating a part of the electronic device of FIG. 1.

Referring to FIGS. 7A and 7B, the electronic device 1 may include the substrate 100, a display panel 10 including a display panel layer DLI disposed on the substrate 100, and the cover window 70. In an embodiment, the cover window 70 may be disposed on a front surface of the display panel 10. The ‘front surface’ may be defined as a surface on which a user may see an image provided by the electronic device 1. Also, the electronic device 1 may include the display circuit board 30 and the main circuit board 50. However, the electronic device 1 may further include a heat dissipation sheet, and a bracket, a battery, a camera device, and a lower cover, as described with reference to FIG. 2.

A blocking layer 71 may be disposed on one surface of the cover window 70. The blocking layer 71 may correspond to the light-blocking cover portion NDA70 of FIG. 2. In this case, the blocking layer 71 may include an opaque material that blocks light. In this case, the blocking layer 71 may be disposed between an outer side of a display area and an end of the cover window 70 without overlapping the display area of the display panel, or may be disposed inside an end of the cover window 70 while overlapping at least a part of the display area.

An adhesive layer ADR may be disposed between the cover window 70 and the display panel layer DLI. In this case, the adhesive layer ADR may include an optically clear adhesive (OCA) or an optically clear resin (OCR) formed of a transparent material. A part of the blocking layer 71 may be inserted into the adhesive layer ADR. In another embodiment, although not shown, the adhesive layer ADR may be disposed on a side surface of the blocking layer 71.

In an embodiment, the cover window 70 may be disposed on a top surface 100a of the substrate 100, and the display panel layer DLI may be disposed between the substrate 100 and the cover window 70. In this case, the display panel layer DLI may refer to a layer from the buffer layer 201 to the encapsulation layer 300 or a layer from the buffer layer 201 to the input sensing layer 400 shown in FIG. 6. For convenience of explanation, the following will be described in detail assuming that the display panel layer DLI is a layer up to the input sensing layer 400.

The top surface 100a of the substrate 100 may refer to one surface of the substrate 100 adjacent to the cover window 70, and a bottom surface 100b of the substrate 100 may refer to a surface opposite to the top surface 100a of the substrate 100.

Hereinafter, the “top surface” refers to a surface facing the cover window 700 with respect to the substrate 100, that is, a surface facing a z direction, and the “bottom surface” refers to a surface opposite to the top surface, that is, a surface facing an opposite direction of the z direction.

In an embodiment, the display circuit board 30 may at least partially overlap the substrate 100. In an embodiment, the display circuit board 30 may at least partially overlap a pad area. For example, the display circuit board 30 may be attached to the top surface 100a of the substrate 100 by using a nonconductive adhesive film. Alternatively, the display circuit board 30 may be attached to the top surface 100a of the substrate 100 through an adhesive.

In an embodiment, the display circuit board 30 may at least partially overlap the main circuit board 50. For example, the display circuit board 30 may be attached to a top surface of the main circuit board 50 by using an anisotropic conductive film. Alternatively, the display circuit board 30 may be attached to the top surface of the main circuit board 50 through an adhesive. However, the disclosure is not limited thereto. The display circuit board 30 may be attached to a bottom surface of the main circuit board 50.

In an embodiment, the display circuit board 30 may be bent along the bending axis BAX. In detail, at least a part of the display circuit board 30 may be bent along the bending axis BAX extending in the first direction (the x direction). In an embodiment, because at least a part of the display circuit board 30 is bent along the bending axis BAX, at least a part of the display circuit board 30 and the main circuit board 50 may be located on the bottom surface 100b of the substrate 100. Accordingly, because at least a part of the display circuit board 30 and the main circuit board 50 are located on the bottom surface 100b of the substrate 100, the area of the peripheral area PA that is a non-display area may be reduced. That is, the area of a dead space may be reduced.

In an embodiment, the data driver 20 may be disposed on the display circuit board 30. Also, the display circuit board 30 may include a first flexible film 31, a second flexible film 33, and wirings 32. In this case, the first flexible film 31 may include at least one of polystyrene, polyvinyl alcohol, polymethyl methacrylate, polyether sulfone, polyacrylate, polyether imide, polyethylene naphthalate, polyethylene terephthalate, polyphenylene sulfide, polyarylate, polyimide, polycarbonate, triacetate cellulose, and cellulose acetate propionate. However, a material of the first flexible film 31 may be changed in various ways, and the first flexible film 31 may be formed of fiber-reinforced plastic or the like.

In an embodiment, the wirings 32 may be formed of a metal. For example, the wirings 32 may be formed of at least one of metals such as gold (Au), silver (Ag), aluminum (Al), molybdenum (Mo), chromium (Cr), titanium (Ti), nickel (Ni), neodymium (Nd), and copper (Cu), or an alloy of the metals. Also, the wirings 32 may have a single-layer structure, but the disclosure is not limited thereto. The wirings 32 may have a multi-layer structure in which two or more of the above metals and the above alloys are stacked. However, the disclosure is not limited thereto.

In an embodiment, the second flexible film 33 may be disposed on the wirings 32. For example, the second flexible film 33 may cover the wirings 32. The second flexible film 33 may be formed of the same material as the first flexible film 31. However, the disclosure is not limited thereto. In an embodiment, the second flexible film 33 may be formed of a different material from the first flexible film 31. However, even when the second flexible film 33 is formed of a different material from the first flexible film 31, the second flexible film 33 may be formed of an insulating material.

At least a part of the wirings 32 may be exposed to the outside to form the circuit board pad 34. The circuit board pad 34 may be in direct contact with and electrically connected to a pad connection electrode 1300.

The pad connection electrode 1300 may be connected to the pad 14. In this case, a separate insulating layer ILL (hereinafter, may also be referred to as “an upper insulating layer OL”) may be disposed between the pad 14 and the display panel layer DLI. The insulating layer ILL may block a part of the pad 14 and may expose another part of the pad 14 to the outside. The pad connection electrode 1300 may be directly connected to a portion of the pad 14 exposed through the insulating layer ILL. Also, a part of the pad connection electrode 1300 may be disposed on a top surface of the insulating layer ILL to be exposed to the outside. A lighting circuit CU and/or an anti-static circuit ECM may be disposed in a lower portion of the insulating layer ILL. For convenience of explanation, the following will be described in detail assuming that the lighting circuit CU and the anti-static circuit ECM are disposed in the lower portion of the insulating layer ILL.

The insulating layer ILL may include an inorganic insulating layer and/or an organic insulating layer in the display panel layer DLI. For example, the insulating layer ILL may include a buffer layer, a first gate insulating layer, a first interlayer insulating layer, a second interlayer insulating layer, a second gate insulating layer, a third interlayer insulating layer, a first organic insulating layer, a second organic insulating layer, a bank layer, a spacer, and/or an organic encapsulation layer of FIG. 6 in the display panel layer DLI. At least a part of the insulating layer ILL may extend from the display panel layer DLI. In another embodiment, although not shown, the insulating layer ILL may be disconnected from a portion of the insulating layer disposed in the display panel layer DLI.

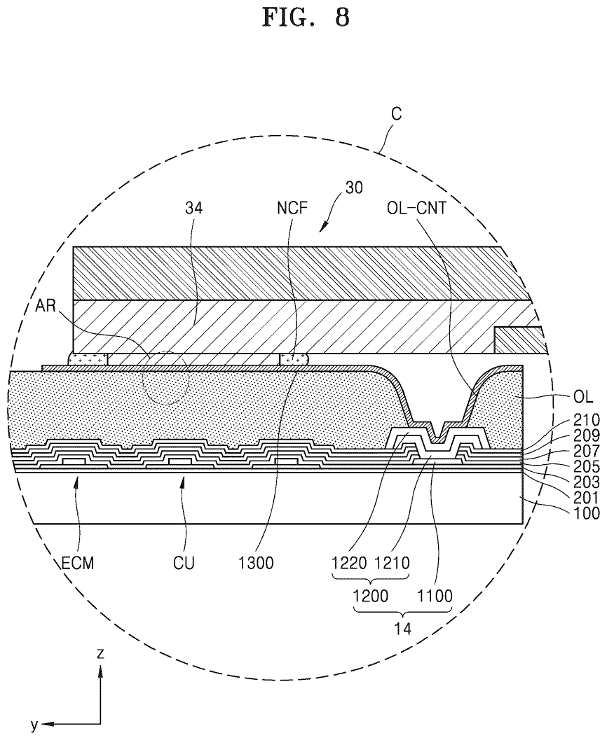

FIG. 8 is an enlarged cross-sectional view illustrating a portion C of FIGS. 7A and 7B.

Referring to FIG. 8, the pad 14 may include a connection line 1100 and a pad electrode 1200. In this case, a plurality of pads 14 may be provided, and the plurality of pads 14 may be spaced apart from each other.

The pad electrode 1200 on the substrate 100 may be in contact with and electrically connected to the connection line 1100.

The connection line 1100 may be disposed on the first gate insulating layer 203, and may include the same material as the lower electrode CE1 of the storage capacitor Cst and/or the first gate electrode GE1 described with reference to FIG. 6. In another embodiment, the connection line 1100 may be disposed on the substrate 100 and may be a separate metal layer. For convenience of explanation, the following will be described in detail assuming that the connection line 1100 is disposed on the first gate insulating layer 203.

At least one insulating layer, for example, the first interlayer insulating layer 205, the second interlayer insulating layer 207, the second gate insulating layer 209, and the third interlayer insulating layer 210, may be disposed on the connection line 1100, and the pad electrode 1200 may be connected to the connection line 1100 through a contact hole passing through the first interlayer insulating layer 205, the second interlayer insulating layer 207, the second gate insulating layer 209, and the third interlayer insulating layer 210.

The pad electrode 1200 may include one conductive layer or may have a structure in which a plurality of conductive layers are stacked. For example, as shown in FIG. 8, the pad electrode 1200 may include at least one of a first pad conductive layer 1210 and a second pad conductive layer 1220.

The first pad conductive layer 1210 may include the same material as the upper electrode CE2 of the storage capacitor Cst, the node connection line 166, or the lower gate electrode G3A of the third gate electrode GE3 described with reference to FIG. 6. The second pad conductive layer 1220 may include the same material as the upper gate electrode G3B of the third gate electrode GE3, the node connection line 166, or the data line DL and/or the driving voltage line PL described with reference to FIG. 6. For convenience of explanation, the following will be described in detail assuming that the first pad conductive layer 1210 is formed of the same material as the node connection line 166, and the second pad conductive layer 1220 is formed of the same material as the data line DL and/or the driving voltage line PL.

Although the first pad conductive layer 1210 and the second pad conductive layer 1220 are in direct contact with each other, the disclosure is not limited thereto. In another embodiment, a pad insulating layer (e.g., an inorganic insulating layer and/or an organic insulating layer) may be disposed between the first pad conductive layer 1210 and the second pad conductive layer 1220, and the first pad conductive layer 1210 and the second pad conductive layer 1220 may be connected to each other through a contact hole of the pad insulating layer.

An upper insulating layer OL may be disposed on the second pad conductive layer 1220. For example, the upper insulating layer OL may include at least one of the first organic insulating layer 211, the second organic insulating layer 213, the bank layer 215, and the spacer 217. In detail, when the second pad conductive layer 1220 includes the same material as the upper gate electrode G3B of the third gate electrode GE3 or the node connection line 166, the upper insulating layer OL disposed on the second pad conductive layer 1220 may include at least one of the first organic insulating layer 211, the second organic insulating layer 213, the bank layer 215, and the spacer 217. In another embodiment, when the second pad conductive layer 1220 is formed of the same material as the data line DL and/or the driving voltage line PL, the upper insulating layer OL may include at least one of the second organic insulating layer 213, the bank layer 215, and the spacer 217. For convenience of explanation, the following will be described in detail assuming that the upper insulating layer OL is the second organic insulating layer 213.

The upper insulating layer OL may define a pad contact hole OL-CNT. In this case, the pad contact hole OL-CNT may pass through the upper insulating layer OL, and the pad electrode 1200 may be exposed to the outside of the upper insulating layer OL through the pad contact hole OL-CNT.

The pad connection electrode 1300 may be connected to the pad electrode 1200 through the pad contact hole OL-CNT. In this case, the pad connection electrode 1300 may include the same material as the first conductive line 420 and/or the second conductive line 440 described with reference to FIG. 6.

The pad connection electrode 1300 may be connected to the pad electrode 1200 and may extend to a flat top surface of the upper insulating layer OL. In this case, the pad connection electrode 1300 may extend to an area where at least one of the lighting circuit CU and the anti-static circuit ECM is disposed. At least a portion of the pad connection electrode 1300 may overlap at least one of the lighting circuit CU and the anti-static circuit ECM in a plan view. In another embodiment, the pad connection electrode 1300 may not overlap the lighting circuit CU and the anti-static circuit ECM. For example, the pad connection electrode 1300 may extend from the pad contact hole OL-CNT to an area where the lighting circuit CU and the anti-static circuit ECM are disposed. Alternatively, the pad connection electrode 1300 may be disposed between adjacent lighting circuits CU and between adjacent anti-static circuits ECM.

The circuit board pad 34 may be disposed on the pad connection electrode 1300. In this case, the pad connection electrode 1300 and the circuit board pad 34 may be directly connected to each other. In other cases, a nonconductive adhesive film NCF may be disposed around the pad connection electrode 1300 and the circuit board pad 34 to connect the pad connection electrode 1300 to the circuit board pad 34. Accordingly, the display circuit board 30 may be connected to the display panel 10. In particular, the display circuit board 30 may be disposed closer to the display panel layer DLI of FIGS. 7A and 7B than when attached to the pad electrode 1200. Also, the display panel 10 may reduce a space for coupling the display circuit board 30. Because a radius of curvature of a bending area of the display circuit board 30 when the display circuit board 30 is attached to the pad connection electrode 1300 and the display circuit board 30 is bent is greater than a radius of curvature of a bending area of the display circuit board 30 when the display circuit board 30 is attached to the pad electrode 1200 and the display circuit board 30 is bent, a compressive force or a tensile force generated in the bending area of the display circuit board 30 may be reduced.

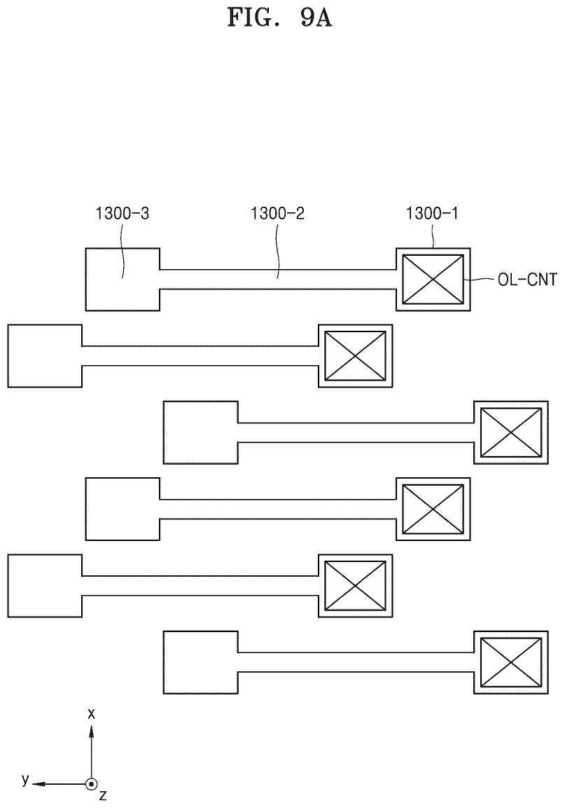

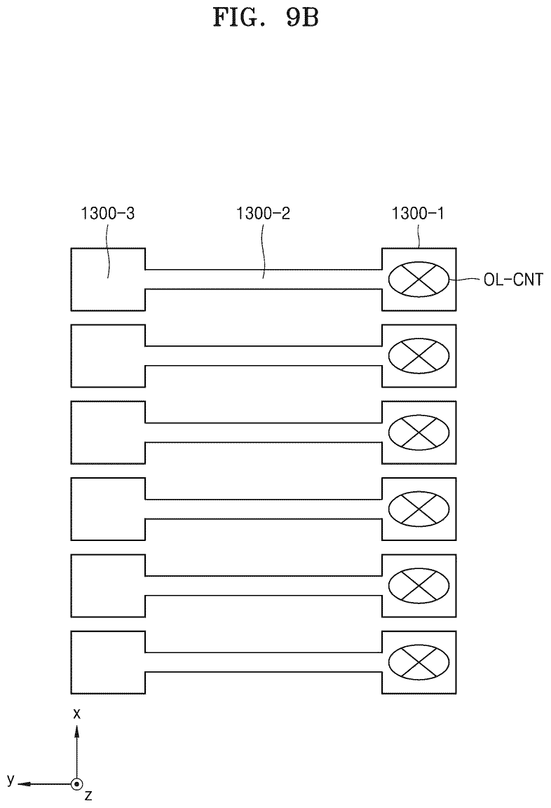

FIG. 9A is a plan view schematically illustrating a pad connection electrode of FIG. 8.

Referring to FIG. 9A, the pad connection electrode 1300 may include a first portion 1300-1 corresponding to the pad contact hole OL-CNT, a second portion 1300-2 connected to the first portion 1300-1, and a third portion 1300-3 contacting the circuit board pad 34. In this case, a width of a planar shape of the first portion 1300-1 and/or a width of a planar shape of the third portion 1300-3 may be greater than a width of a planar shape of the second portion 1300-2. Also, the area of a planar shape of the first portion 1300-1 may be greater than the area of a planar shape of the pad contact hole OL-CNT. In this case, a planar shape of the pad contact hole OL-CNT may be disposed inside a planar shape of the first portion 1300-1. Accordingly, because the first portion 1300-1 completely covers the pad contact hole OL-CNT, the pad connection electrode 1300 may be electrically connected to the pad electrode 1200. Although not shown, the first portion 1300-1, the second portion 1300-2, and the third portion 1300-3 may be formed in a linear shape. In another embodiment, a planar shape of the first portion 1300-1 and/or a planar shape of the third portion 1300-3 may be a polygonal shape, a circular shape, an elliptical shape, or an irregular shape. In another embodiment, the second portion 1300-2 may have a curved shape or a serpentine shape, rather than a linear shape as shown in FIG. 9A.

A plurality of pad connection electrodes 1300 may be provided. In this case, a plurality of circuit board pads 34 may be provided to respectively correspond to the pad connection electrodes 1300.

The plurality of pad connection pads 1300 may be arranged so as not to overlap each other in a plan view. In this case, the pad contact hole OL-CNT corresponding to each pad connection electrode 1300 may be arranged in a zigzag shape or a serpentine shape in the x direction. For example, in a direction (e.g., x direction) different from a longitudinal direction (y direction) of the pad connection electrode 1300, one of a plurality of pad contact holes OL-CNT may be disposed at a position different from another one of the plurality of pad contact holes OL-CNT. Accordingly, a space where each pad contact hole OL-CNT is formed may be secured, and a space where adjacent pad connection electrodes 1300 are disposed may be secured.

FIG. 9B is a plan view schematically illustrating a pad connection electrode of a display panel, according to another embodiment.

Referring to FIG. 9B, the pad connection electrode 1300 may include the first portion 1300-1, the second portion 1300-2, and the third portion 1300-3. In this case, a plurality of pad connection electrodes 1300 may be aligned. That is, the first portions 1300-1 of the pad connection electrodes 1300 may be aligned in a direction (e.g., x direction) different from the longitudinal direction (y direction) of the pad connection electrode 1300.

A planar shape of the pad contact hole OL-CNT may be an elliptical shape. In this case, because a distance between adjacent pad contact holes OL-CNT in the x direction is secured, adjacent pad connection electrodes 1300 may be arranged without overlapping each other, and may shield each pad contact hole OL-CNT.

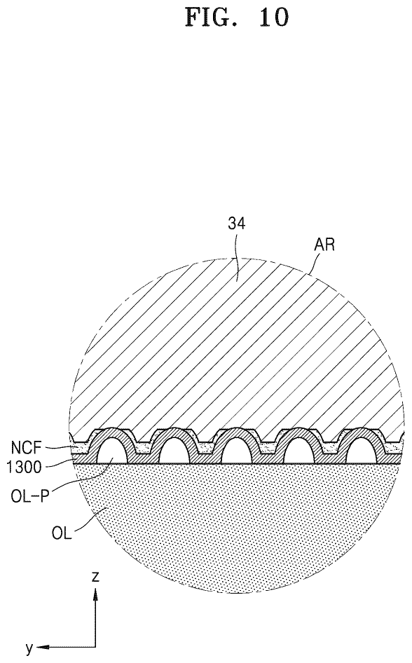

FIG. 10 is a cross-sectional view schematically illustrating a part of a display panel, according to another embodiment. FIG. 10 is an enlarged cross-sectional view schematically illustrating a portion corresponding to an portion AR of FIG. 8 in the display panel, according to another embodiment.

Referring to FIG. 10, a protrusion OL-P may be provided on the upper insulating layer OL and under the pad connection electrode 1300. In this case, the protrusion OL-P may protrude from a top surface of the upper insulating layer OL toward the pad connection electrode 1300. The protrusion OL-P may provide a curve to a top surface of the pad connection electrode 1300 to increase a coupling force between the pad connection electrode 1300 and the circuit board pad 34.

The protrusion OL-P may be integrally formed with the upper insulating layer OL or may be formed separately from the upper insulating layer OL. For example, when the protrusion OL-P is integrally formed with the upper insulating layer OL, the upper insulating layer OL may be formed and then the protrusion OL-P may be formed on a surface of the upper insulating layer OL by etching the surface of the upper insulating layer OL. In another embodiment, when the protrusion OL-P is formed separately from the upper insulating layer OL, if the upper insulating layer OL is formed of the same material as the first organic insulating layer 211 of FIG. 6, the protrusion OL-P may be formed of the same material as at least one of the second organic insulating layer 213, the bank layer 215, the spacer 217, and the organic encapsulation layer 320 of FIG. 6. In another embodiment, when the upper insulating layer OL is formed of the same material as the second organic insulating layer 213 of FIG. 6, the protrusion OL-P may be formed of the same material as at least one of the bank layer 215, the spacer 217, and the organic encapsulation layer 320 of FIG. 6. In another embodiment, when the upper insulating layer OL is formed of the same material as the bank layer 215 of FIG. 6, the protrusion OL-P may be formed of the same material as at least one of the spacer 217 and the organic encapsulation layer 320 of FIG. 6. In another embodiment, when the upper insulating layer OL is formed of the same material as the spacer 217 of FIG. 6, the protrusion OL-P may be formed of the same material as the organic encapsulation layer 320 of FIG. 6.

As described above, the pad connection electrode 1300 whose surface is formed in an uneven shape due to the protrusion OL-P may contact the circuit board pad 34 through the nonconductive adhesive film NCF. In this case, the pad connection electrode 1300 and the circuit board pad 34 may be connected through thermal compression or ultrasonic bonding.

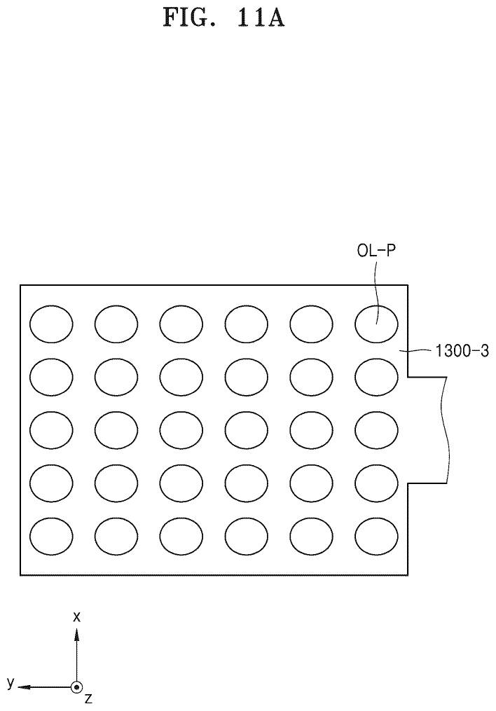

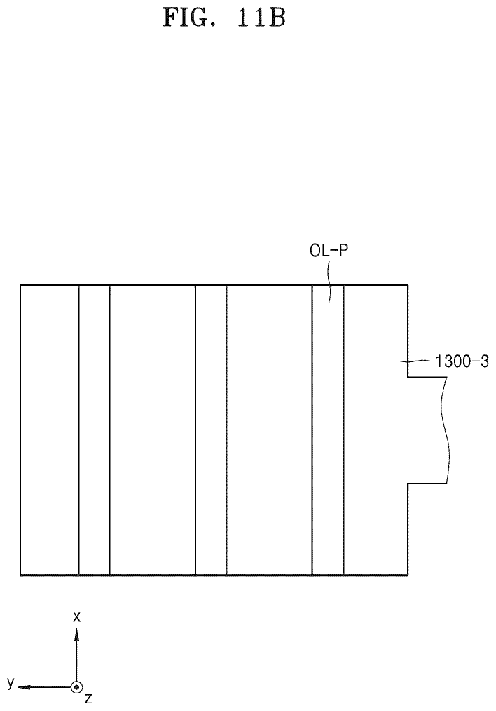

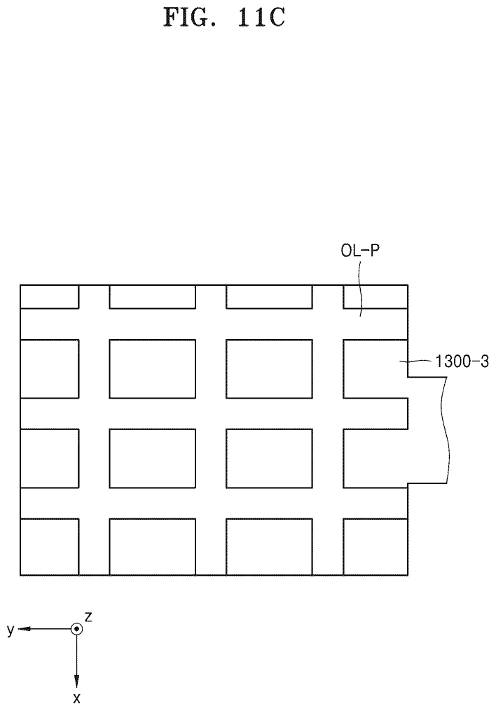

FIGS. 11A to 11C are plan views schematically illustrating a protrusion of FIG. 10.

Referring to FIG. 11A, the third portion 1300-3 of the pad connection electrode may include the protrusion OL-P. A plurality of protrusions OL-P may be provided. In this case, a planar shape of the protrusion OL-P may be any of various shapes. For example, a planar shape of the protrusion OL-P may be a circular shape, and may be an island shape. In this case, the protrusion OL-P may have a shape such as a hemispherical shape, a cylindrical shape, or a cone shape. The plurality of protrusions OL-P may be spaced apart from each other. In this case, distances between adjacent protrusions OL-P may be constant. In another embodiment, distances between adjacent protrusions OL-P may be different from each other.

Although not shown, a planar shape of the protrusion OL-P is not limited thereto. For example, a planar shape of the protrusion OL-P may include a polygonal shape and/or an elliptical shape. Also, a planar shape of the protrusion OL-P may be an irregular shape such as a star shape or a cross shape, excluding a circular shape, a polygonal shape, and an elliptical shape.

Referring to FIG. 11B, a planar shape of the protrusion OL-P may be a linear shape. In this case, the protrusions OL-P may be arranged to be spaced apart from each other in one direction. Widths of planar shapes of the protrusions OL-P may be the same or different from each other. Also, in addition to an arrangement direction illustrated in FIG. 11B, the protrusions OL-P may be obliquely arranged or may be arranged in a direction perpendicular to the arrangement direction of FIG. 11B.

Referring to FIG. 11C, the protrusions OL-P may be arranged in a lattice shape. In this case, a planar shape of an area where the protrusions OL-P are not disposed may be a quadrangular shape. In this case, a shape of an area where the protrusions OL-P are not disposed is not limited thereto, and may be any of various shapes. For example, a shape of an area where the protrusions OL-P are not disposed may include a circular shape, a polygonal shape, and/or an elliptical shape or may include an irregular shape such as a star shape or a cross shape excluding a circular shape, a polygonal shape, and an elliptical shape.

A display panel and an electronic device according to embodiments may reduce an area where an image is not displayed.

The display panel and the electronic device according to embodiments may rapidly and accurately transmit a signal provided from a display circuit board to a display panel.

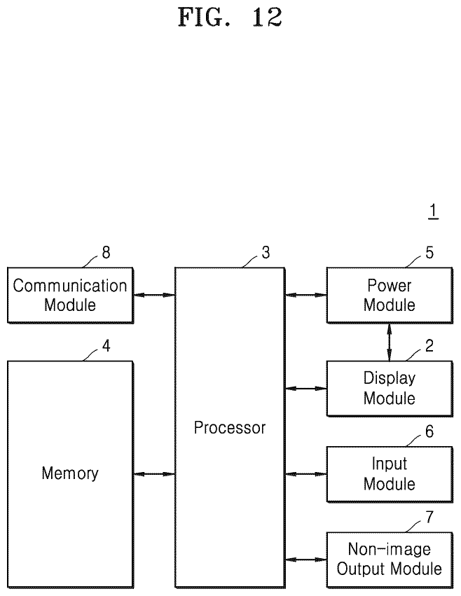

FIG. 12 is a block diagram of an electronic device, according to an embodiment.

Referring to FIG. 12, the electronic device 1 according to an embodiment may include a display module 2 including a display panel, a processor 3, a memory 4, and a power module 5.

The processor 3 may include at least one of a central processing unit (CPU), an application processor (AP), a graphics processing unit (GPU), a communication processor (CP), an image signal processor (ISP), and a controller. According to an embodiment, the processor 3 may be provided by being divided into two or more processors in a functional or structural perspective. For example, the processor 3 may include a main processor as a first driving chip including a CPU and an auxiliary processor as a second driving chip including a controller configured to receive an image signal from the main processor and process the image signal according to the interface specifications of the display module 2.

The memory 4 may include at least one of a non-volatile memory and a volatile memory. The memory 4 may store data information necessary for operations of the processor 3 or the display module 2. When the processor 3 executes an application stored in the memory 4, an image data signal and/or an input control signal may be transmitted to the display module 2, and the display module 2 may be configured to process the received signal and output image information through a display screen.

The power module 5 may include a power supply module, such as a power adaptor or a battery device, and a power conversion module configured to convert a power supplied from the power supply module and generate power necessary for operations of the electronic device 1. The power conversion by the power conversion module may include direct current (DC)-DC conversion, alternating current (AC)-DC conversion, and DC-AC conversion, but is not limited thereto.

The electronic device 1 may further include an input module 6, a non-image output module 7, and/or a communication module 8.

The input module 6 may provide input information to the processor 3 and/or the display module 2. The input module 6 may include not only a physical button, a keyboard, and a microphone, but also various sensor modules. Examples of the sensor modules may include not only a touch sensor, a pressure sensor, a distance sensor, a position sensor, a digitizer, a motion recognition sensor, a camera sensor, a light reception sensor, a photoelectric conversion sensor, and a temperature sensor, but also biometric sensors, such as a blood-pressure sensor, a blood-sugar sensor, an electrocardiogram sensor, a heart rate sensor, etc.

The non-image output module 7 may receive information except for an image from the processor 3 and provide the information to a user. Examples of the non-image output module 7 may include a sound module, a haptic module, a light-emission module, etc. and may also include other functionally intrinsic modules (for example, a cooling module of a refrigerator, etc.) of an electronic device 1.

The communication module 8 may be configured to perform transmission and reception of information between the electronic device 1 and an external device and may include a receiver and a transmitter. The communication module 8 may include various wireless communication modules, such as a mobile communication module, a WiFi module, a Bluetooth module, etc., or various wired communication modules.

At least one of the components of the electronic device 1 described above may be included in the display panel 10 according to the embodiments described above. Also, some of separate modules functionally included in the electronic device 1 may be included in the electronic device 1 and the others may be provided separately from the electronic device 1. For example, the electronic device 1 may include the display module 2, and the processor 3, the memory 4, and the power module 5 may be provided in the electronic device 1, rather than the display module 2, as other devices. As another example, the power module 5 may be provided in the electronic device 1 and may provide a power supply to the processor 3 and the memory 4 which are provided in the electronic device 1, rather than the display module 2. However, the disclosure is not limited thereto.

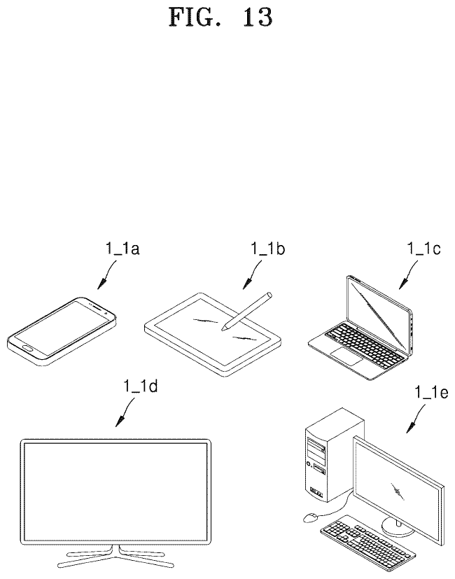

FIGS. 13 to 15 are schematic views of electronic devices according to various embodiments. FIGS. 13 to 15 illustrate examples of various electronic devices in which the display panel 10 according to embodiments is included.

FIG. 13 illustrates a smartphone 1_1a, a tablet PC 1_1b, a laptop computer 1_1c, a TV 1_1d, and a monitor 1_1e for a desk, as examples of the electronic devices.

The smartphone 1_1a may include an input module, such as a touch sensor, etc., and a communication module, in addition to the display module 2. The smartphone 1_1a may process information received through the communication module or other input modules and display the processed information through a display module 2 of the electronic device 1.

The tablet PC 1_1b, the laptop computer 1_1c, the TV 1_1d, and the monitor 1_1e for a desk may also include a display module and an input module, similarly as the smartphone 1_1a, and may further include a communication module according to cases.

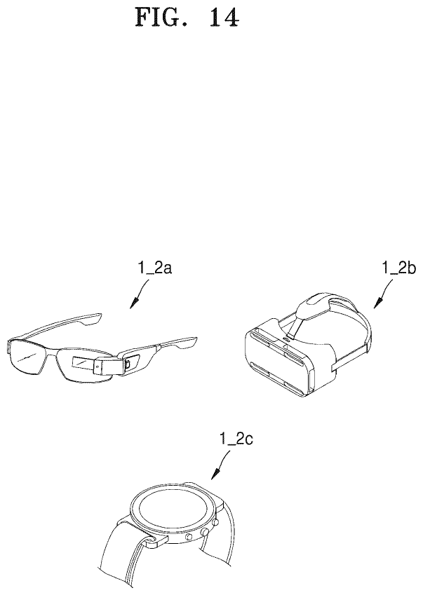

FIG. 14 illustrates a case where the electronic device 1 including the display module 2 includes a wearable electronic device. The wearable electronic device may include smart glasses 1_2a, an HMD 1_2b, a smart watch 1_2c, etc.

The smart glasses 1_2a and the HMD 1_2b may include a display module 2 configured to project a display image and a reflector configured to reflect the projected display screen and provide the display screen to a user's eye, so as to provide a screen of virtual reality (VR) or augmented reality (AR) to the user.

The smart watch 1_2c may include a biometric sensor as an input device and may provide biometric information recognized through the biometric sensor to the user through a display module 2.

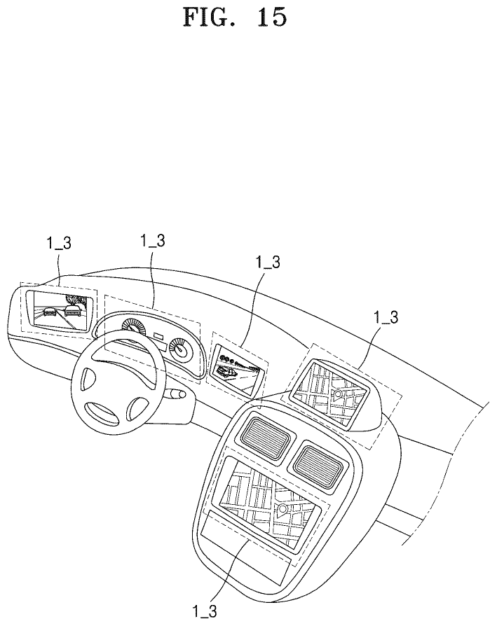

FIG. 15 illustrates a case where the electronic device 1 including the display module 2 includes a vehicle. For example, an electronic device 1_3 may be used in a gauge or a center fascia of the vehicle, or may be used as a CID arranged on a dashboard of the vehicle, or a room mirror display substituting a side-view mirror.

Although not shown, the electronic device in which the display panel 10 according to embodiments is included, may include not only devices mainly including a screen display, such as an advertisement board, an electronic display board, a game machine, etc., but also various home appliances for displaying information through a display module, such as a refrigerator, a laundry machine, a dryer, an air conditioner, a robot cleaner, etc. Also, when the display module has a light-transmission function, the electronic device may include a smart window or a transparent display panel for displaying the background and a display image together. Types of the electronic device according to an embodiment are not limited to the examples described above, and various other electronic devices may also be provided.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope as defined by the claims.

What is claimed is:

1. A display panel comprising:
a substrate comprising a display area and a peripheral area;
a pad disposed in the peripheral area of the substrate and comprising a pad electrode;
an insulating layer disposed on the pad and defining an opening through which at least a part of the pad electrode is exposed to outside; and
a pad connection electrode connected to the pad electrode through the opening, at least a part of the pad connection electrode being disposed on the insulating layer.

2. The display panel of claim 1, wherein the opening is provided in plurality,
wherein the plurality of openings are arranged in one direction crossing a longitudinal direction of the pad connection electrode in a plan view.

3. The display panel of claim 1, wherein the opening is provided in plurality,
wherein the plurality of openings are arranged in a serpentine shape in one direction crossing a longitudinal direction of the pad connection electrode in a plan view.

4. The display panel of claim 1, wherein the opening has an elliptical shape in a plan view.

5. The display panel of claim 1, wherein the pad connection electrode comprises an uneven portion in a cross-sectional view.

6. The display panel of claim 1, further comprising a protrusion disposed on the insulating layer and protruding toward the pad connection electrode.

7. The display panel of claim 6, wherein the protrusion is provided in plurality,
wherein the plurality of protrusions are arranged under a part of the pad connection electrode in a plan view and are spaced apart from each other.

8. The display panel of claim 6, wherein the protrusion has a linear shape in a plan view.

9. The display panel of claim 6, wherein the protrusion has a lattice shape in a plan view.

10. The display panel of claim 1, wherein the insulating layer comprises an organic material.

11. An electronic device comprising:
a display panel; and
a circuit board connected to the display panel and comprising a circuit board pad,
wherein the display panel comprises:
a substrate comprising a display area and a peripheral area;
a pad disposed in the peripheral area of the substrate and comprising a pad electrode;
an insulating layer disposed on the pad and defining an opening through which at least a part of the pad electrode is exposed to outside; and
a pad connection electrode connected to the pad electrode through the opening and contacting the circuit board pad, at least a part of the pad connection electrode being disposed on the insulating layer.

12. The electronic device of claim 11, wherein the opening is provided in plurality,
wherein the plurality of openings are arranged in one direction crossing a longitudinal direction of the pad connection electrode in a plan view.

13. The electronic device of claim 11, wherein the opening is provided in plurality,
wherein the plurality of openings are arranged in a serpentine shape in one direction crossing a longitudinal direction of the pad connection electrode in a plan view.

14. The electronic device of claim 11, wherein the opening has an elliptical shape in a plan view.

15. The electronic device of claim 11, wherein the pad connection electrode comprises an uneven portion in a cross-sectional view.

16. The electronic device of claim 11, further comprising a protrusion disposed on the insulating layer and protruding toward the pad connection electrode.

17. The electronic device of claim 16, wherein the protrusion is provided in plurality,
wherein the plurality of protrusions are disposed under a part of the pad connection electrode in a plan view and are spaced apart from each other.

18. The electronic device of claim 16, wherein the protrusion has a linear shape in a plan view.

19. The electronic device of claim 16, wherein the protrusion has a lattice shape in a plan view.

20. The electronic device of claim 16, wherein the insulating layer comprises an organic material.
